(19) United States
(12) Patent Application Publication
(10) Pub. No.: US 2016/0012916 A1
(43) Pub. Date: Jan. 14, 2016

(54) SEMICONDUCTOR MEMORY DEVICE AND MEMORY SYSTEM

(71) Applicant: KABUSHIKI KAISHA TOSHIBA, Minato-ku (JP)

(72) Inventors: Tokumasa HARA, Kawasaki (JP); Takuya HAGA, Yokohama (JP)

(73) Assignee: KABUSHIKI KAISHA TOSHIBA, Minato-ku (JP)

(21) Appl. No.: 14/482,777

(22) Filed: Sep. 10, 2014

Related U.S. Application Data
(60) Provisional application No. 62/023,060, filed on Jul. 10, 2014.

(51) Int. Cl. G11C 29/38; G11C 16/26; G11C 29/50; G11C 16/04

(52) U.S. Cl. CPC G11C 29/38; G11C 16/0483; G11C 16/26; G11C 29/50004

(57) ABSTRACT

According to one embodiment, a semiconductor memory device includes: transistors; NAND strings; a bit line; a source line; and string sets. The transistors are stacked above a semiconductor substrate. In one of the string sets, a first transistor in a first NAND string has a first threshold, and a first transistor in a second NAND string has a second threshold lower than the first threshold.

### CROSS-REFERENCE TO RELATED APPLICATIONS

This application claims the benefit of U.S. Provisional Application No. 62/023,060, filed Jul. 10, 2014, the entire contents of which are incorporated herein by reference.

### FIELD

Embodiments described herein relate generally to a semiconductor memory device.

### BACKGROUND

A NAND flash memory is known in which memory cells are three-dimensionally arranged.

### BRIEF DESCRIPTION OF THE DRAWINGS

FIG. 1 is a block diagram of a memory system according to a first embodiment;

FIG. 2 is a block diagram of a semiconductor memory device according to the first embodiment;

FIG. 3 and FIG. 4 are a circuit diagram and a cross-sectional view of a memory cell array according to the first embodiment;

FIG. 5 is a diagram showing threshold distributions for memory cells according to the first embodiment;

FIG. 6 and FIG. 7 are flowcharts of a test method according to the first embodiment;

FIG. 8 is a circuit diagram of the memory cell array according to the first embodiment;

FIG. 9 is a timing chart of various signals according to the first embodiment;

FIG. 10 is a circuit diagram of the memory cell array according to first the embodiment;

FIG. 11 is a timing chart of various signals according to the first embodiment;

FIG. 12 is a flowchart of a test method according to a second embodiment;

FIG. 13 is a schematic diagram of page data according to the second embodiment;

FIG. 14 is a diagram showing threshold distributions for memory cells according to a third embodiment;

FIG. 15 is a timing chart of a bit line potential according to the third embodiment;

FIG. 16 is a flowchart of a test method according to a fourth embodiment;

FIG. 17 is a block diagram of a semiconductor memory device according to the fourth embodiment;

FIG. 18 is a flowchart of a test method according to the fourth embodiment;

FIG. 19 and FIG. 20 are flowcharts of a write operation according to a fifth embodiment;

FIG. 21 is a schematic diagram of page data according to the fifth embodiment;

FIG. 22 is a flowchart of a read operation according to the fifth embodiment;

FIG. 23 is a schematic diagram of page data according to the fifth embodiment;

FIG. 24 is a schematic diagram of page data;

FIG. 25 and FIG. 26 are a circuit diagram and a cross-sectional view of a memory cell array according to a sixth embodiment;

FIG. 27 is a diagram showing threshold distributions for memory cells according to the first embodiment; and

FIG. 28 and FIG. 29 are circuit diagrams of a memory cell array according to the sixth embodiment.

### DETAILED DESCRIPTION

In general, according to one embodiment, a semiconductor memory device includes: a plurality of transistors; a plurality of NAND strings; a bit line; a source line; and a plurality of string sets. Each of the transistors includes a charge accumulation layer and a control gate and is stacked above a semiconductor substrate. Each of the NAND strings includes a plurality of the transistors connected in series. The bit line is electrically connected to a one end of a first transistor positioned on a one end side of the series connection. The source line is electrically connected to a one end of a second transistor positioned on another end side of the series connection. Each of the string sets includes a plurality of the NAND strings. In one of the string sets, the first transistor in a first NAND string has a first threshold, and the first transistor in a second NAND string has a second threshold lower than the first threshold.

### 1. FIRST EMBODIMENT

First, a semiconductor memory device and a memory system according to a first embodiment will be described.

### 1.1 Configuration of the Memory System

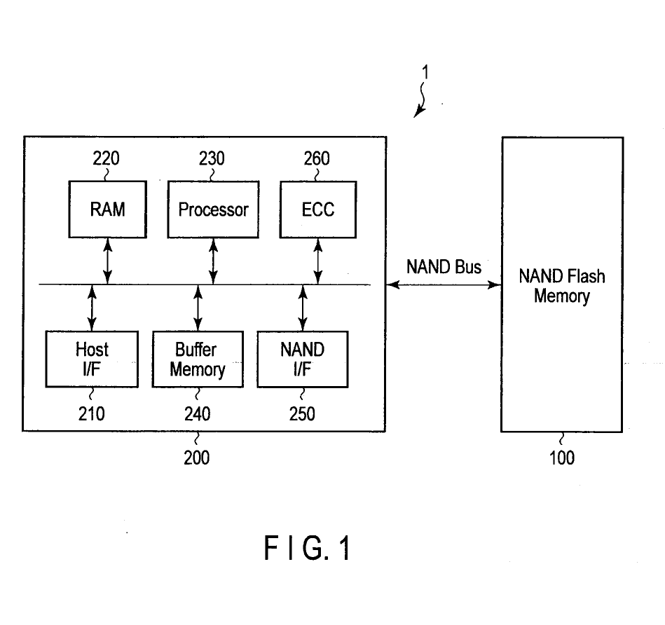

First, a configuration of a memory system according to the first embodiment will be described with reference to FIG. 1. FIG. 1 is a block diagram of the memory system according to the first embodiment.

As shown in FIG. 1, the memory system 1 includes a NAND flash memory 100 and a memory controller 200. The controller 200 and the NAND flash memory 100 may, for example, be combined together to provide one semiconductor device, for example, a memory card such as an SDTM card or an SSD (Solid State Drive).

The NAND flash memory 100 includes a plurality of memory cells to store data in a nonvolatile manner. A configuration of the NAND flash memory 100 will be described below in detail.

The controller 200 instructs the NAND flash memory to perform a read operation, a write operation, an erase operation, or the like in response to an instruction from external host device. Furthermore, the controller 200 manages memory spaces in the NAND flash memory 100.

The controller 200 includes a host interface circuit 210, an embedded memory (RAM) 220, a processor 230, a buffer memory 240, a NAND interface circuit 250, and an ECC circuit 260.

The host interface circuit 210 is connected to the host device through a controller bus to control communication with the host device. The host interface circuit 210 transfers a command and data received from the host device to a processor 230 and a buffer memory 240. Furthermore, in response to an instruction from the processor 230, the host interface circuit 210 transfers data in the buffer memory 240 to the host device.

The NAND interface circuit 250 is connected to the NAND flash memory 10 through a NAND bus to control communication with the NAND flash memory 100. The NAND flash interface circuit 250 transfers a command received from the processor 230 to the NAND flash memory 100, and transfers write data in the buffer memory 240 to the NAND flash memory 100 in a write operation. Moreover, the NAND interface circuit 250 transfers data read from the NAND flash memory 10 to the buffer memory 240 in a read operation.

The processor 230 performs overall control of the controller 200. For example, upon receiving a write instruction from the host device, the processor 230 issues a write command based on the NAND interface in response to the write instruction. It similarly operates in the case of read and erase operations. The processor 230 also executes various processes such as wear leveling for managing the NAND flash memory 100. Moreover, the processor 230 executes various kinds of arithmetic operations. For example, the processor 230 executes a data encryption process, a randomization process, and the like.

The ECC circuit 260 executes a data error correction (ECC: Error Checking and Correcting) process. That is, the ECC circuit 260 generates a parity based on write data in a data write operation, and generates a syndrome from the parity in a read operation to detect an error and corrects the error. The processor 230 may have functions of the ECC circuit 260.

The embedded memory 220 is a semiconductor memory, for example, a DRAM and is used as a work area for the processor 230. The embedded memory 220 holds firmware for managing the NAND flash memory 100, various management tables, and the like.

### 1.1.2 General Configuration of the Semiconductor Storage Device

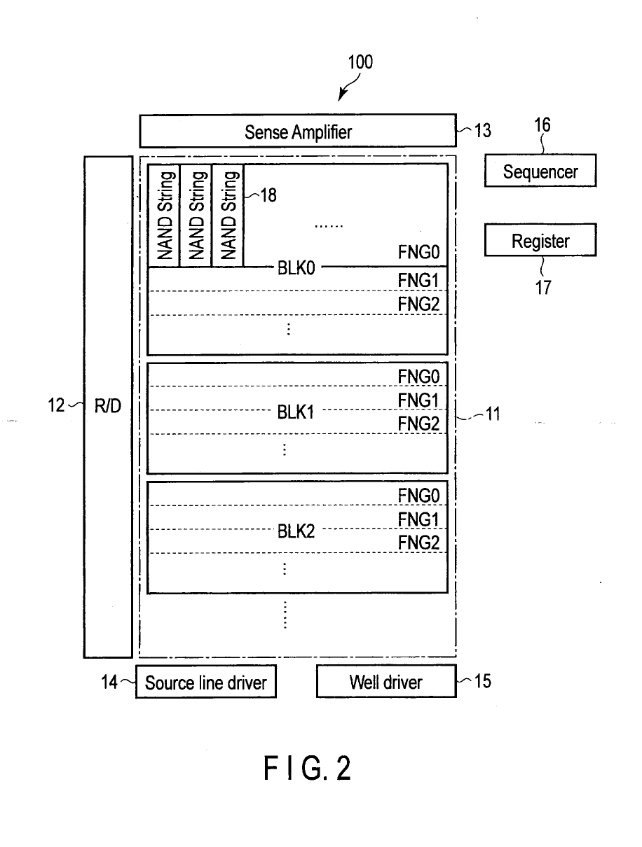

Now, a configuration of the NAND flash memory 100 will be described. FIG. 2 is a block diagram of the NAND flash memory 100 according to the first embodiment. As shown in FIG. 2, the NAND flash memory 100 includes a memory cell array 11, a row decoder 12, a sense amplifier 13, a source line driver 14, a well driver 15, a sequencer 16, and a register 17.

The memory cell array 11 includes a plurality of blocks BLK (BLK0, BLK1, BLK2, . . . ) that is a set of a plurality of nonvolatile memory cells each associated with a word line and a bit line. The block BLK corresponds to a data erase unit, and the data in the same block BLK is erased simultaneously. Each of the blocks BLK includes a plurality of fingers FNG (FNG0, FNG1, FNG2, . . . ) that is a set of NAND strings 18 in which the memory cells are connected in series. Of course, the number of blocks in the memory cell array 11 and the number of fingers FNG in one block BLK are optional.

The row decoder 12 decodes a block address and a page address to select one of word lines WL in the corresponding block BLK. The row decoder 12 then applies appropriate voltages to the selected word line and unselected word lines.

The sense amplifier 13 senses and amplifies data read from a memory cell onto a bit line BL in a data read operation. The sense amplifier 13 transfers write data to a memory cell in a data write operation. Data is read from and written to the memory cell array 11 in units of a plurality of memory cells, and this unit corresponds to a page.

The source line driver 14 applies a voltage to the source line SL.

The well driver 15 applies a voltage to a well region where the NAND string 18 is formed.

The register 17 holds various signals. For example, the register 17 holds the status of a data write or erase operation to notify the controller 200 whether or not the controller 200 has operated normally. Alternatively, the register 17 holds commands, addresses, and the like received from the controller 200 and can also hold various tables.

The sequencer 16 performs overall control of the NAND flash memory 100.

### 1.1.3 Memory Cell Array

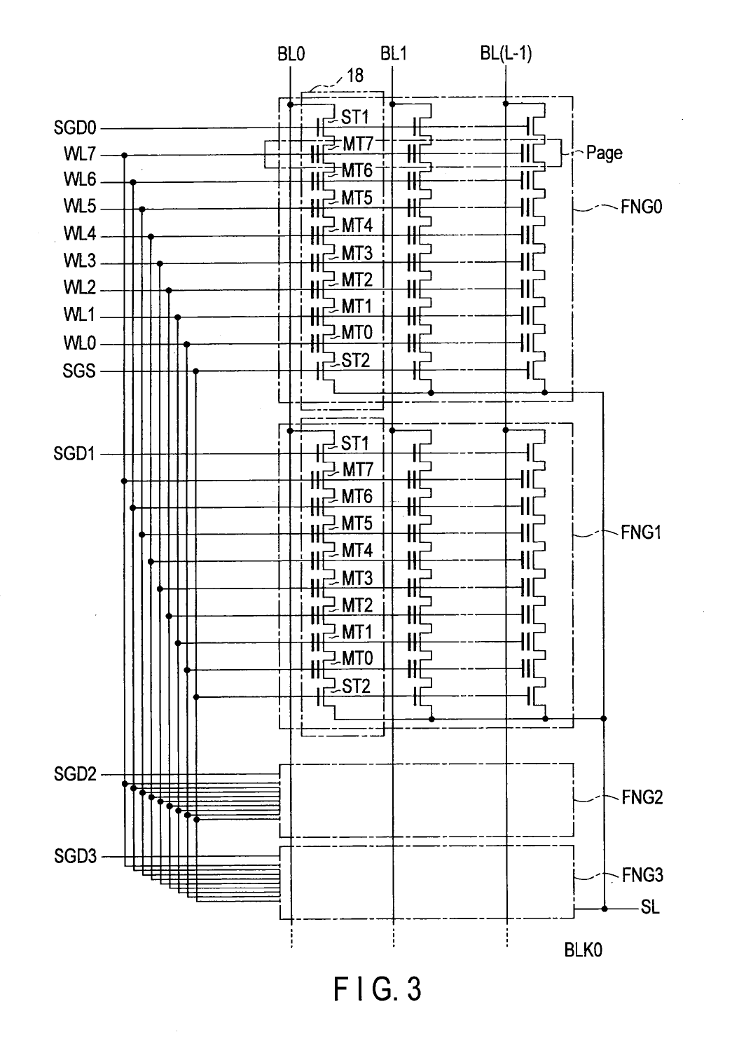

Now, the configuration of the memory cell array 11 will be described in detail. FIG. 3 is a circuit diagram of one of the blocks BLK, and the other blocks BLK have similar configurations.

As shown in FIG. 3, the block BLK includes four fingers FNG (FNG0 to FNG3). Each of the fingers FNG includes a plurality of NAND strings 18.

Each of the NAND strings 18 includes, for example, eight memory cell transistors MT (MT0 to MT7) and selection transistors ST1 and ST2. The memory cell transistors MT and the selection transistors ST1 and ST2 each include a stacked gate including a control gate and a charge accumulation layer and hold data in a nonvolatile manner. The number of memory cell transistors MT is not limited to 8 but may be 16, 32, 64, 128, or the like; the number of the memory cell transistors MT is not limited. The memory cell transistors MT are arranged between the selection transistors ST1 and ST2 so that current paths in the memory cell transistors MT are connected together in series. The current path in the memory cell transistor MT7 at a first end of the series connection is connected to a first end of the current path in the selection transistor ST1. The current path in the memory cell transistor MT0 at a second end of the series connection is connected to a first end of the current path in the selection transistor ST2.

Gates of the selection transistors ST1 in each of the fingers FNG0 to FNG3 are all connected to a corresponding one of selection gate lines SGD0 to SGD3. On the other hand, in each of the plurality of fingers FNG, gates of the selection transistors ST2 are all connected to a selection gate line SGS. Furthermore, control gates of the memory cell transistors MT0 to MT7 in the same block BLK0 are connected to the same word lines WL0 to WL7, respectively.

That is, the memory cell transistors in the plurality of fingers FNG0 to FNG3 in the same block BLK are connected to the same the word lines WL0 to WL7 and the same selection gate line SGS, whereas, even in the same block BLK, the independent selection gate lines SGD are provided for the fingers FNG0 to FNG3, respectively.

Furthermore, for the NAND strings 18 arranged in a matrix in the memory cell array 11, second ends of the current paths in the selection transistors ST1 in the NAND stings 18 on the same row are commonly connected to one of the bit lines BL (BL0 to BL(L−1); (L−1) is a natural number equal to or larger than 1). That is, the bit line BL connects the NAND strings 18 in common over the blocks BLK. Additionally, second ends of the current paths in the selection transistors ST2 are commonly connected to the same source line SL. The source line SL, for example, connects the NAND strings in common over the blocks.

As described above, the data in the memory cell transistors MT in the same block BLK is collectively erased. In contrast, a data read operation and a data write operation are collectively performed on a plurality of memory cell transistors MT connected to one of the word lines WL in one of the fingers FNG in one of the blocks BLK. This unit is a “page”.

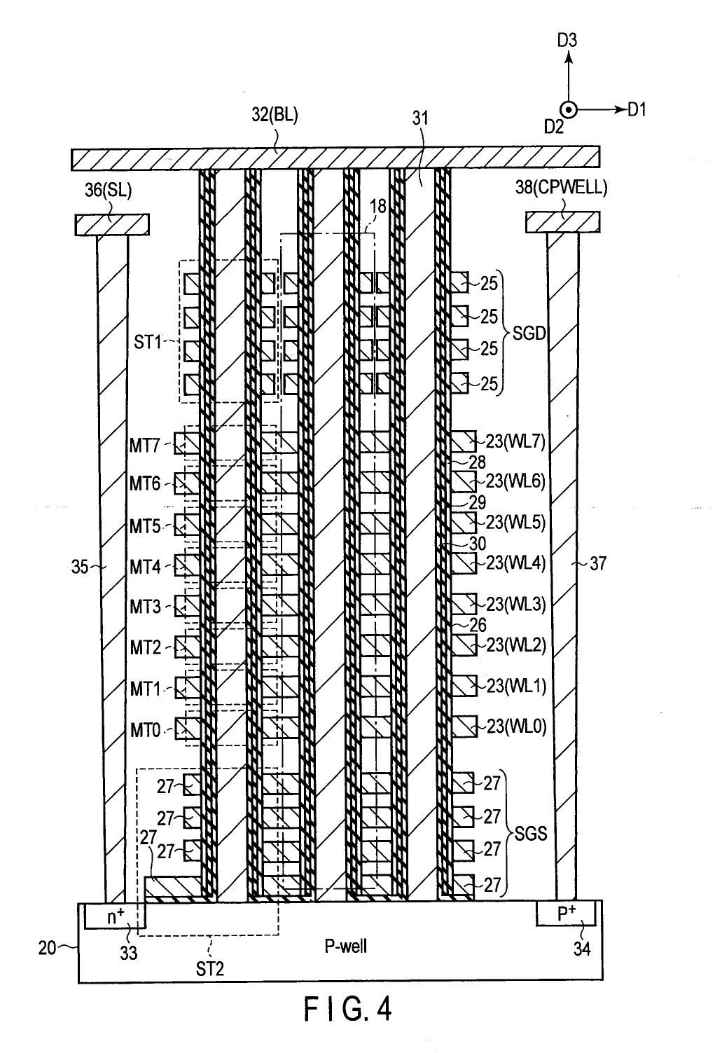

FIG. 4 is a cross-sectional view of a partial area of the memory cell array 18 according to the first embodiment. As shown in FIG. 4, a plurality of NAND strings 18 are formed on a p-type well region 20. That is, the following are formed above the well region 20: a plurality of interconnect layers 27 functioning as the selection gate lines SGS, a plurality of interconnect layers 23 functioning as the word lines WL, and a plurality of interconnect layers 25 functioning as the selection gate lines SGD.

Memory holes 26 are formed which penetrate the interconnect layers 25, 23, and 27 to reach the well region 20. A block insulating film 28, a charge accumulation layer 29 (insulating film), and a gate insulating film 28 are sequentially formed on a side surface of each of the memory holes 26. Moreover, a conductive film 31 is filled in the memory hole 26. The conductive film 31 is an area functioning as the current path of the NAND string 18 and in which a channel is formed when the memory cell transistor MT and the selection transistors ST1 and ST2 operate.

In each of the NAND strings 18, a plurality of (in the present example, four) interconnect layers 27 are electrically connected together and are connected to the same selection gate line SGS. That is, the four interconnect layers 27 function as a gate electrode of substantially one selection transistor ST2. This also applies to the selection transistor ST1 (four-layer select gate line SGD).

In the above-described configuration, in each of the NAND strings 18, the selection transistor ST2, the plurality of memory cell transistors MT, and the selection transistor ST1 are sequentially stacked on the well region 20.

In the example in FIG. 4, each of the selection transistors ST1 and ST2 includes the charge accumulation layer 29 similarly to the memory cell transistor MT. However, each of the selection transistors ST1 and ST2 does not substantially function as a memory cell that stores data but functions as a switch. In this case, thresholds at which the selection transistors ST1 and ST2 are turned on and off can be controlled by injecting charge into the charge accumulation layer 29.

An interconnect layer 32 functioning as the bit line BL is formed at an upper end of the conductive film 31. The bit line BL is connected to the sense amplifier 13.

Moreover, an n⁺-type impurity diffusion layer 33 and a p⁺-type impurity diffusion layer 34 are formed in a surface of the well region 20. A contact plug 35 is formed on the diffusion layer 33, and an interconnect layer 36 functioning as the source line SL is formed on a contact plug 35. The source line SL is connected to the source line driver 14. Furthermore, a contact plug 37 is formed on the diffusion layer 34, and an interconnect layer 38 functioning as a well interconnect CPWELL is formed on the contact plug 37. The well interconnect CPWELL is connected to the well driver 15. The interconnect layers 36 and 38 are formed in a layer located above the selection gate line SGD and below the interconnect layer 32.

A plurality of the above-described configurations are arranged in a direction away from the reader with respect to the sheet of FIG. 4. A set of the plurality of NAND strings 18 arranged in this direction forms one finger FNG. The interconnect layers 27 functioning as the plurality of selection gate lines SGS included in the same finger FNG are connected together. In other words, gate insulating films 30 are also formed on the well region 20 between the adjacent NAND strings 18, and the semiconductor layers 27 and gate insulating films 30 adjacent to the diffusion layer 33 are formed to extend to the vicinity of the diffusion layer 33.

Thus, when the selection transistor ST2 is turned on, the corresponding channel electrically connects the memory cell transistor MT0 and the diffusion 33 together. Furthermore, applying a voltage to the well interconnect CPWELL allows a potential to be applied to the conductive film 31.

The memory cell array 11 may have another configuration. That is, the configuration of the memory cell array 11 is described in, for example, U.S. patent application Ser. No. 12/407,403 entitled “Three-dimensional Stacked Nonvolatile Semiconductor Memory” filed on Mar. 19, 2009, the disclosure of which is hereby incorporated by reference in its entirety. The configuration of the memory cell array 11 is also described in U.S. patent application Ser. No. 12/406,524 entitled “Three-dimensional Stacked Nonvolatile Semiconductor Memory” filed on Mar. 18, 2009, the disclosure of which is hereby incorporated by reference in its entirety. The configuration of the memory cell array 11 is also described in U.S. patent application Ser. No. 12/679,991 entitled “Non-volatile Semiconductor Storage Device and Method of Manufacturing the Same” filed on Mar. 25, 2010, the disclosure of which is hereby incorporated by reference in its entirety. The configuration of the memory cell array 11 is also described in U.S. patent application Ser. No. 12/532,030 entitled “Semiconductor Memory and Method for Manufacturing Same” filed on Mar. 23, 2009, the disclosure of which is hereby incorporated by reference in its entirety.

### 1.2 Method for Testing the Memory Cell Array

Now, a method for testing the memory cell array 11 configured as described above will be described. According to the present method, when a defect is present in the memory cell array 11, the relevant information (hereinafter referred to as defect information) is managed for each of the NAND strings 18. The defect information is written to at least one of the selection transistors ST1 and ST2. This inhibits the use of a defective NAND string. The present method will be described.

### 1.2.1 Threshold Distributions

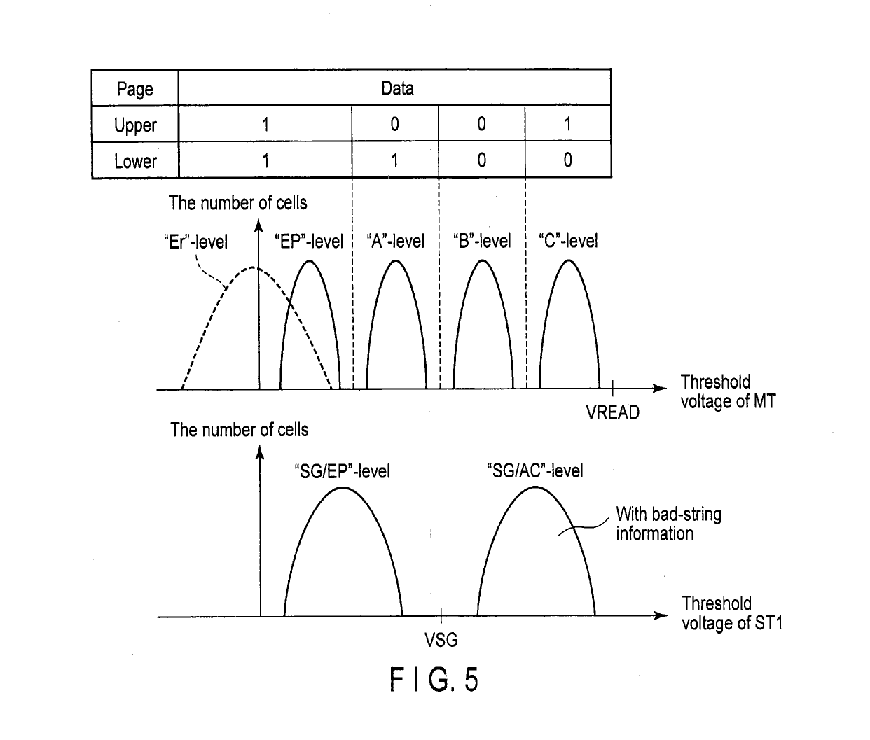

First, threshold distributions for the memory cell transistor MT and the selection transistors ST1 and ST2 will be described. FIG. 5 is a graph showing data that can be taken by the memory cell transistor MT according to the first embodiment and threshold distributions for the memory cell transistor MT and the selection transistors ST1 and ST2.

As shown in FIG. 5, each of the memory cell transistors MT can hold, for example, 2 bit data in accordance with the threshold for the memory cell transistor MT. The 2 bit data is, for example, “11”, “01”, “00”, and “10” in order of increasing threshold.

The threshold for a memory cell holding the “11” data is an “Er” level or an “EP” level. The Er level is a threshold for a state where charge is removed from the charge accumulation layer to erase the data and may have not only a positive value but also a negative value. The EP level is a threshold for a state where charge is injected into the charge accumulation layer. The EP level is equal to or higher than the Er level and has a positive value.

“01”, “00”, and “10” are also thresholds for the state where charge is injected into the charge accumulation layer. The threshold for a memory cell holding the “01” data is an “A” level that is higher than the Er level and the EP level. The threshold for a memory cell holding the “00” data is a “B” level that is higher than the A level. The threshold for a memory cell holding the “10” data is a “C” level that is higher than the B level. Of course, the relation between the 2 bit data and the threshold is not limited to the above-described relation. For example, the “11” data may correspond to the “C” level. The relation between the 2 bit data and the threshold may be appropriately selected.

Next, the threshold distributions for the selection transistors ST1 and ST2 will be described. As shown in FIG. 5, the threshold for the selection transistors ST1 and ST2 are normally an “SG/EP” level. The threshold corresponds to a level at which the selection transistors ST1 and ST2 are turned on when a voltage VSG is applied to the selected selection gate lines SGD and SGS in a normal read operation. The voltage is, for example, between the EP level and the A level.

In contrast, when the defect information is written to the selection transistor ST1 or ST2, the threshold for the selection transistor ST1 and ST2 is set to an “SG/AC” level. This level is higher than VSG and is, for example, between the B level and the C level. Thus, writing the defect information to the selection transistor ST1 or ST2 causes the selection transistor ST1 or ST2 to be constantly off in a read operation and in a write operation

### 1.2.2 Method for Detecting Defect and Writing Defect Information

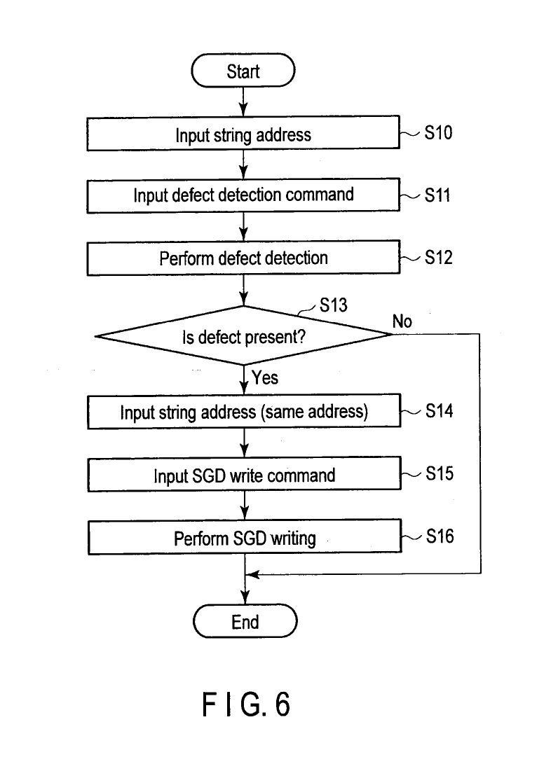

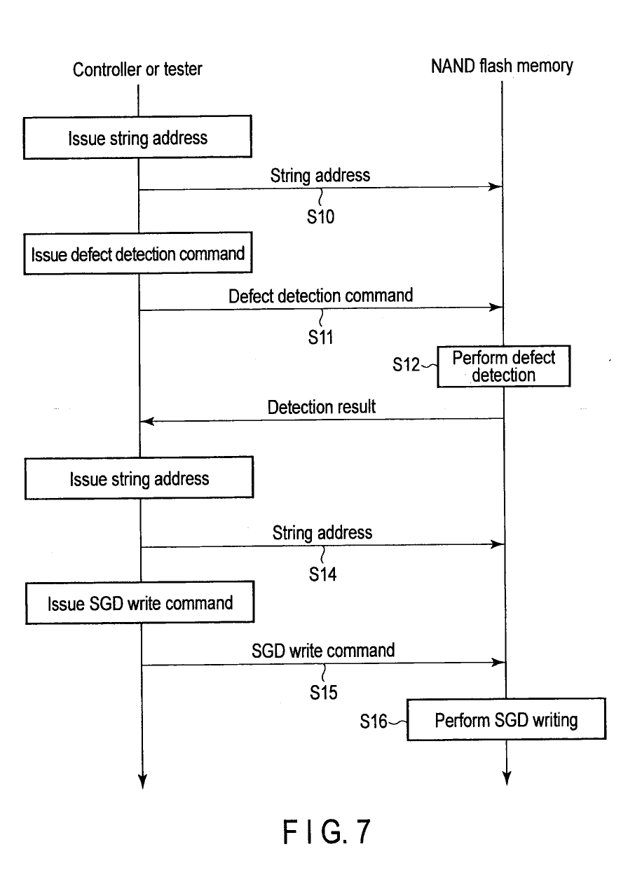

Now, a method for testing the memory cell array 11 configured as described above will be described. FIG. 6 and FIG. 7 are flowcharts showing a test method according to the first embodiment. FIG. 7 shows a flow of processing executed by the controller 200 and the NAND flash memory 100 when a defect is present in FIG. 6. The test is performed by the controller 200 or a tester that tests the NAND flash memory 100. The processor 230 mainly operates in the controller 200, and the sequencer 16 mainly operates in the NAND flash memory 100. By way of example, a case will be described where the controller 200 tests the NAND flash memory 100. When the tester performs tests, the “controller 200” may be replaced with the “tester” below.

As shown in FIG. 6 and FIG. 7, first, the processor 230 of the controller 200 issues and transmits a string address to the NAND flash memory 100 (step S10). The string address is an address used to specify the finger FNG to be tested for a defect. In the NAND flash memory 100, the received string address is held, for example, in an address register that is a part of the register 17.

The processor 230 of the controller 200 issues and transmits a defect detection command to the NAND flash memory 100 (step S11). The transmitted command is held, for example, in a command register that is a part of the register 17. In response to the defect detection command being held in the command register, the sequencer 16 of the NAND flash memory 100 performs a defect detection test on the finger FNG specified by the string address stored in the address register (step S12).

The defect detection test in step S12 is performed by sensing a current or a voltage on the bit line BL when a voltage VREAD is applied to all the word lines in the finger FNG to be tested. The sequencer 16 determines that the corresponding NAND string 18 is defective when no current flows through the bit line BL. Step S12 will be described below in detail.

After step S12 is executed, the sequencer 16 of the NAND flash memory 100 transmits a defect detection result to the controller 200. In this case, the defect detection result may be transmitted from the NAND flash memory 100 to the controller 200 in the form of, for example, a defect detection signal or the defect detection result may be stored in any of the registers in the register 17 so that the controller 200 can read the information in the register 17.

The processor 230 of the controller 200 determines whether or not a defect is present in the finger FNG corresponding to the string address input in step S10, based on the defect detection result for the NAND flash memory 100. When no defect is present in the finger FNG (step S13, NO), the process ends. A similar test is performed on another finger FNG as needed.

On the other hand, when a defect is present in the finger FNG (step S13, YES), the processor 230 of the controller 200 issues and transmits the same string address as that issued in step S10 to the NAND flash memory 100 (step S14). The string address is stored in the address register in the NAND flash memory 100.

Subsequently, the processor 230 of the controller 200 issues and transmits an SGD write command to the NAND flash memory 100 (step S15). The SGD write command is stored, for example, in the command register. The SGD write command is intended to give an instruction to write defect information to the selection transistor ST1. The defect information is written to the selection transistor ST1 (SGD) in the first embodiment, but may be written to the selection transistor ST2 (SGS). The write data is the defect detection result acquired in step S13. In response to the SGD write command being stored in the command register, the sequencer 16 writes the defect information to the selection transistor ST1 (step S16). As a result, the threshold of the selection transistor ST1 in the NAND string 18 in which the defect is detected is increased from the “SG/EP” level to an “SG/AC” level described with reference to FIG. 5. On the other hand, the threshold of the selection transistor ST1 in the NAND strings 18 in which no defect is detected maintains the “SG/EP” level. The method for writing the defect information will be described below in detail.

The test operation is completed as described above. Of course, a similar process may be executed on another finger FNG as needed.

### 1.2.3 Details of the Method for Detecting a Defect

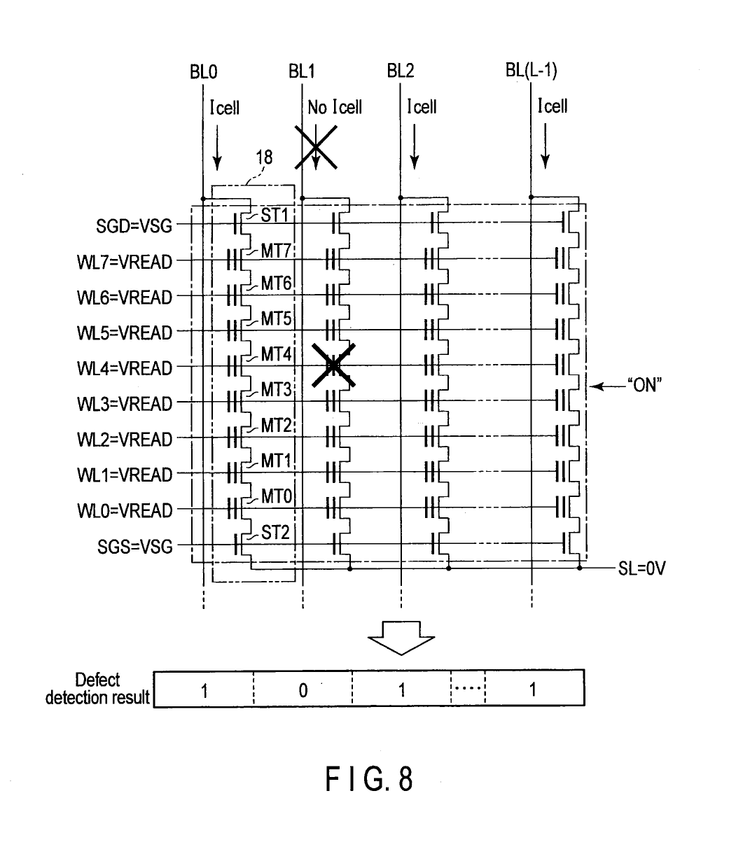

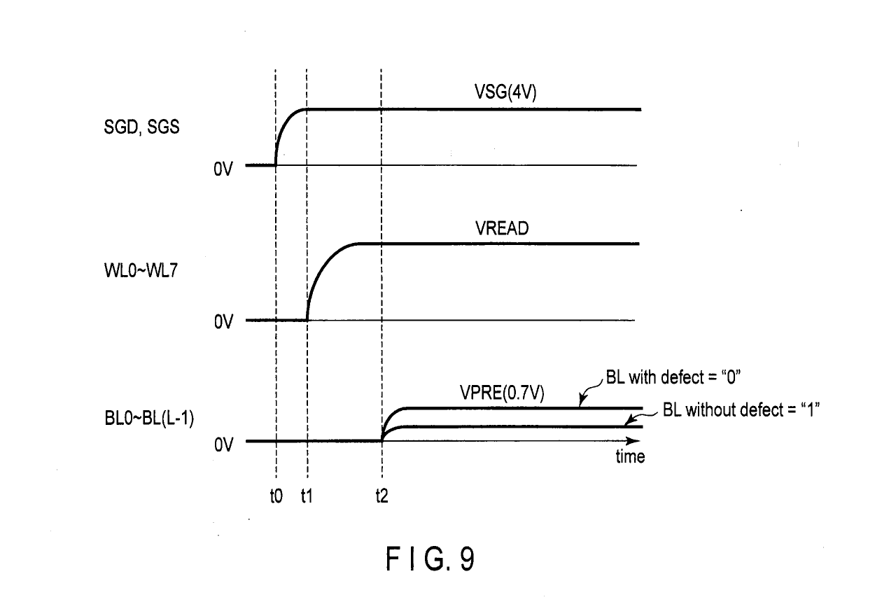

Next, the method for detecting a defective NAND string will be described with reference to FIG. 8 and FIG. 9. FIG. 8 is a circuit diagram of the finger FNG to be tested. FIG. 9 is a timing chart illustrating changes in the voltages of the selection gate lines SGD and SGS, the word line WL, and the bit line BL. A cross shown in FIG. 8 indicates that the corresponding memory cell transistor MT is off, in other words, the memory cell transistor MT is a defective cell.

As shown in figures, the row decoder 12 applies the voltage VSG (for example, 4 V) to the selection gate lines SGD and SGS (time t0). Then, the row decoder 12 applies the voltage VREAD to all the word lines WL0 to WL7 (time t1). The voltage VREAD is a voltage that turns non-defective memory cell transistors MT on, regardless of the data held in the memory cell transistor MT. Subsequently, the sense amplifier 13 precharges the bit line BL to a precharge level VPRE (for example, 0.7 V) (time t2).

As a result, as shown in FIG. 8, when a NAND string 18 in the selected finger FNG does not include a defect, a cell current Icell flows from the bit line BL toward the source line. Thus, as shown in FIG. 9, the potential of the bit line BL becomes lower than the precharge level.

On the other hand, when the NAND string 18 includes a defect, the cell current Icell is prevented from flowing from the bit line BL toward the source line SL (or a very small amount of cell current flows but the amount is much smaller than the amount in an on cell). Thus, as shown in FIG. 9, the potential of the bit line BL is kept at the precharge level.

For example, in the example in FIG. 8, the NAND string 18 connected to the bit line BL1 includes a defect. More specifically, for example, the memory cell transistor MT connected to the word line WL4 is assumed to be a defective cell (the cross in FIG. 8 indicates that the corresponding cell is turned off). Then, the current path in the NAND string 18 is, for example, blocked by the memory cell transistor MT connected to the word line WL4, preventing the flow of the cell current.

In this state, the sense amplifier 13 senses and amplifies a voltage or a current read onto the bit line BL. In the present example, read data resulting from a decrease in the voltage of the bit line BL (turn-on of the memory cell) is defined as “1” data. Read data resulting from the voltage of the bit line BL kept at the precharge level (turn-off of the memory cell) is defined as “0” data. Of course, the definitions may be reversed.

The read data is held by latch circuits provided in the sense amplifier 13 for each of the bit lines BL. That is, as shown in FIG. 8, the “0” data is stored in the latch circuit corresponding to the bit line BL1, with the “1” data stored in the other latch circuits.

As described above, a set of the 0″ data and “1” data obtained for the respective bit lines is the “defect information”. Thus, the defect information has a number of bits corresponding to one page. The defect information may be transmitted to the controller 200 without any change or information indicating which of the bits is “0” may be transmitted to the controller 200 as the “defect information”.

It is assumed that, before the present test is performed, for example, column redundancy is used to remedy such a defect as fixes the read data to “0” or “1” due to, for example, a defect in the bit line BL itself regardless of the result of read from the memory cell.

### 1.2.4. Details of the Method for Writing Defect Information

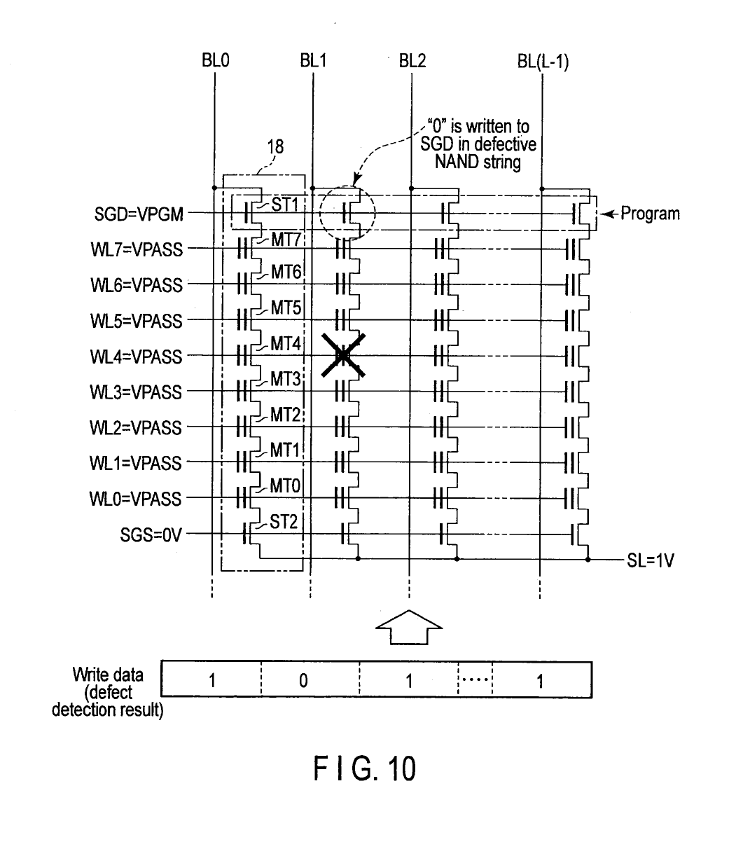

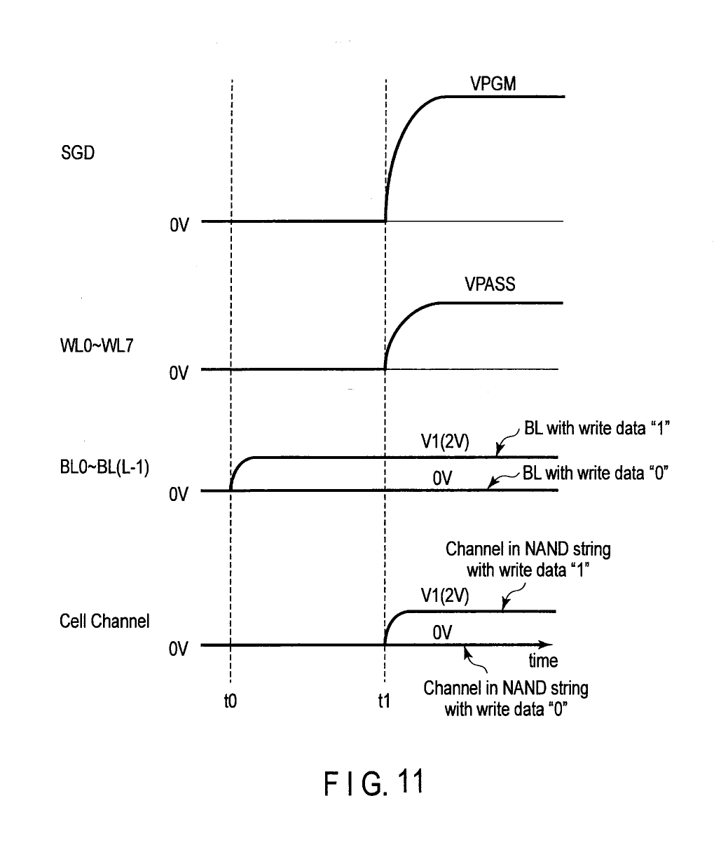

Now, the method for writing the defect information in step S16 will be described in detail with reference to FIG. 10 and FIG. 11. FIG. 10 is a circuit of the finger FNG to be tested. FIG. 11 is a timing chart illustrating changes in the voltages of the selection gate line SGD, the word line WL, the bit line BL, and the channel in the NAND string 18.

The latch circuits in the sense amplifier 13 store the read data obtained in step S12 (see FIG. 10). That is, in an example in FIG. 10, the latch circuit corresponding to the bit line BL1 holds the “0” data, whereas the other latch circuits hold the “1” data. Thus, the sense amplifier 13 applies a voltage to the corresponding bit line BL based on the data held by the latch circuits (time t0). More specifically, the sense amplifier 13 applies the voltage V1 (for example, 2 V) to the bit line BL corresponding to the “0” data, while applying, for example, 0 V (<V1) to the bit line BL corresponding to the “1” data.

Subsequently, the row decoder 12 applies a voltage VPASS to all the word lines WL0 to WL7, while applying a voltage VPGM to the selection gate line SGD (time t1). VPASS is a voltage that turns the non-defective memory cell transistors MT on, regardless of the data held in the memory cell transistor MT. Furthermore, VPGM is a high voltage that generates an FN tunneling phenomenon to allow electrons to be injected into the charge accumulation layer 29. A relation VPGM>VPASS is established. The selection gate line SGS is, for example, 0 V, which keeps the selection transistor ST2 off.

The non-defective memory cell transistors MT and the selection transistor ST1 turns on by the voltage VPASS and VPGM to form a current path (channel) in the NAND string 18. Thus, the voltage applied from the sense amplifier 13 to the bit line BL is transferred to the channel in the NAND string 18.

That is, the channel in the defective NAND string 18 has a voltage of 0 V to allow writing to the selection transistor ST1. In other words, electrons are injected into the charge accumulation layer of the selection transistor ST1 to increase the threshold of the selection transistor ST1. At this time, a write verify voltage is set higher than the voltage VSG. Thus, the threshold of the selection transistor ST1 increases to the “SG/AC” level. On the other hand, the channels in the non-defective NAND strings 18 have a voltage of 2 V, avoiding writing to the selection transistor ST1. In other words, the threshold of the selection transistor ST1 maintains the “SG/EP” level.

### 1. 3 Effect According to the First Embodiment

The configuration according to the first embodiment enables memory spaces to be more efficiently used by managing good and bad memory cells for each of the NAND string 18. This effect will be described below in detail.

For an approach to improve the bit density of NAND flash memories, stacking is expected to replace miniaturization, which is close to the limit. By way of example, a stacked NAND flash memory has been proposed in which vertical transistors are used to stack memory cells.

A technique for stacking involves forming memory holes in stacked word lines at the time and forming memory cells in the memory holes. Stacked control gates (word lines) are connected together among a plurality of strings (a plurality of fingers). Sharing the word lines among the plurality of fingers enables a reduction in the number of metal interconnect layers and in the area of peripheral circuits. A set of the fingers sharing the word lines is the block BLK described with reference to FIG. 2 and FIG. 3.

In a planar NAND flash memory in which memory cells are two-dimensionally arranged on a semiconductor substrate, if any block has a critical defect, the block is handled as a bad block. As a result, the block as a whole is inhibited from being used.

This also applies to the three-dimensional stacked NAND flash memory. However, as described with reference to FIG. 2 and FIG. 3, the three-dimensional stacked NAND flash memory includes very many memory cells in one block. As shown in FIG. 1, the number of memory cells in one string (one finger FNG) in the three-dimensional stacked NAND flash memory is equivalent to one block BLK in the planar NAND flash memory. In other words, one block BLK going bad has an impact comparable to the impact of several blocks BLK simultaneously going bad in the planar NAND flash memory.

In this regard, the configuration according to the first embodiment manages good and bad memory cells for each of the NAND strings 18. More specifically, if any of the NAND strings 18 is defective, this NAND string is handled as an unusable string, whereas the other NAND strings 18 are handled as usable strings. In other words, if a defect occurred in any of the fingers FNG, instead of the whole of this finger being made unusable, only the defective NAND string 18 is made unusable.

To make the defective NAND string 18 unusable, the threshold of the selection transistor ST1 is set to a value higher than the voltage VSG. As a result, during normal operation, the selection transistor ST1 in the defective NAND string 18 is constantly off. In other words, accesses to the NAND string 18 can be inhibited.

As described above, if a defect occurs in any of the fingers FNG, the number of NAND strings handled as a bad string can be minimized. As a result, the memory spaces can be more efficiently used.

### 2. SECOND EMBODIMENT

Now, a semiconductor memory device and a memory system according to a second embodiment will be described. According to the second embodiment, in the test operation described in the first embodiment, a defect detection operation is performed on the same finger FNG a plurality of times, and defect information is obtained based on the result of the defect detection operations. Only differences from the first embodiment will be described below.

### 2.1 Test Method

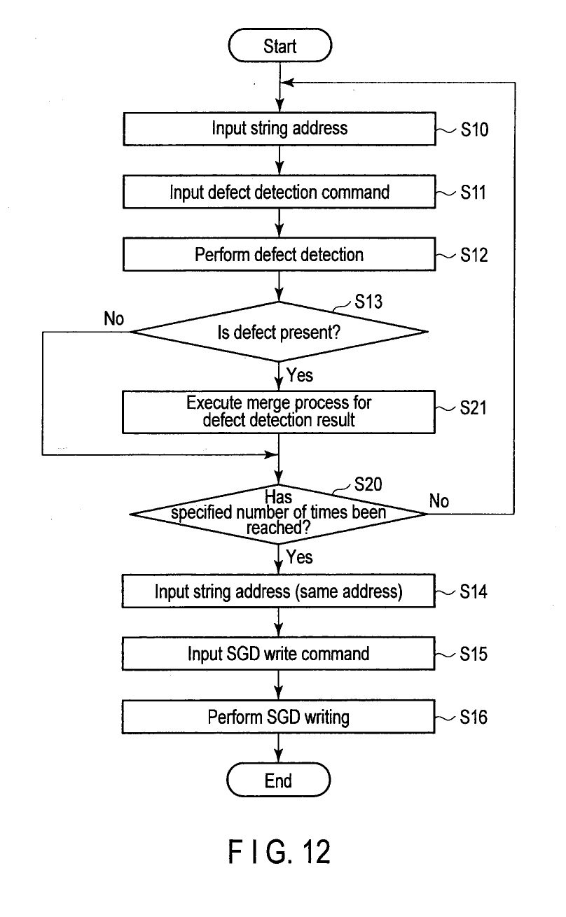

FIG. 12 is a flowchart of a test method according to the second embodiment, and corresponds to FIG. 6 described in the first embodiment. Only differences from the first embodiment will be described.

First, the above-described steps S10 to S13 are executed. If defective NAND string is not detected in step S13 (step S13, NO), a processor 230 of a controller 200 checks the number of defect detection operations performed on the finger FNG. If the number of defect detection operations fails to have reached a specified value (step S20, NO), the processor 230 of the controller 200 executes processing in steps S10 to S13 again. On the other hand, when the number of defect detection operations has reached the specified value (step S20, YES), the repeated process ends, and the processing goes to step S14.

If a defective NAND string is detected in step S13 (step S13, YES), the sense amplifier 13 executes a merge process on defect detection results (step S21). After the process in step S21 completes, the processing goes to step S20.

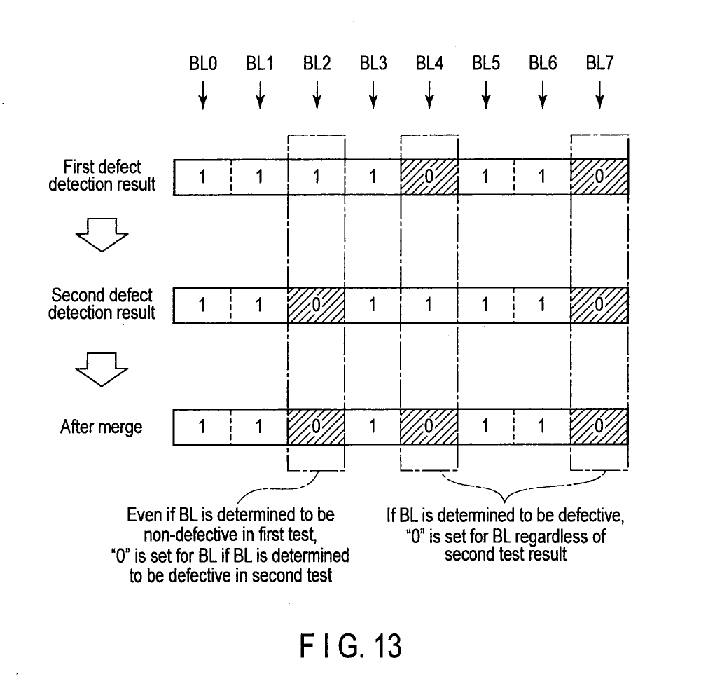

Step S21 will be described in detail using FIG. 13. FIG. 13 shows latch circuits in a sense amplifier 13 holding the first defect detection result, the second defect detection result, and defect information resulting from the merge process based on these bad-string results. In FIG. 13, bits determined to be defect are shaded. Furthermore, for simplification of description, FIG. 13 illustrates a case of eight bit lines, by way of example.

As shown in FIG. 13, it is assumed that, during the first defect detection operation, the NAND strings 18 corresponding to bit lines BL4 and BL7 are determined to be defective. Thus, the latch circuits corresponding to the bit lines BL4 and BL7 hold “0” data, and the other latch circuits hold “1” data. That is, 8 bit data (page data) held in the latch circuits is “11110110”. The 8 bit data is saved to other latch circuits in the sense amplifier 13.

The following is further assumed. When the second defect detection operation is performed, the NAND string 18 corresponding to a bit line BL2 is newly determined to be defective, the NAND string 18 corresponding to the bit line BL4 and determined to be defective during the first defect detection operation is determined to be non-defective, and the bit line BL7 is determined to be defective as in the case of the first defect detection operation. Thus, the latch circuits corresponding to the bit lines BL2 and BL7 hold the “0” data, whereas the other latch circuits hold the “1” data. That is, the 8 bit data held in the latch circuits is “11011110”.

An arithmetic circuit included in the sense amplifier 13 executes a merge process on the 8 bit data indicative of the saved first defect detection result and the 8 bit data indicative of the saved second defect detection result. That is, the defect detection results are merged using the following method.

The bits determined to be non-defective during both the first and second defect detection operations are determined to be non-defective bits. In other words, defect information corresponding to the bits is “1”.

The bits determined to be defective during at least one of the first and second defect detection operations are determined to defective bits. In other words, defect information corresponding to the bits is “0”.

Thus, in the example in FIG. 13, the bits corresponding to the bit lines BL2, BL4, and BL7 are determined to be defective. Hence, the arithmetic circuit generates defect information “11010110”. The defect information “11010110” is held in the latch circuits in the sense amplifier 13. Based on this data, a program is executed on the selection transistor ST1 in step S16.

If the third defect detection operation is performed, the 8 bit data corresponding to the result of the third defect detection operation may be merged with the 8 bit data corresponding to the result of the merger of the first and second defect detection operations.

### 2.2 Effect According to the Second Embodiment

The configuration according to the second embodiment enables an increase in defect detection accuracy, allowing the operational reliability of the memory system to be improved. This effect will be described below.

Defects include a “complete defect” and an “incomplete defect”. The complete defect constantly shows defective behavior at least under normal operating conditions. On the other hand, the incomplete defect sometimes shows non-defective behavior and sometimes shows defective behavior. That is, with the incomplete defect, a defective phenomenon may or may not be observed externally (this is hereinafter referred to as “non-reproducibility” of the defect).

The presence of such an incomplete defect causes a phenomenon where the results of a plurality of defect detections fail to match. Thus, disadvantageously, it is difficult to remedy the defective bits based on the defect detection results (this will be described in a fifth embodiment in detail).

In this regard, according to the second embodiment, defect detection is performed a plurality of times, and a bit determined to be defective at least once is considered to be defective, and defect information is written to the corresponding selection transistor ST1. In other words, a NAND string 18 determined to be defective at least once is inhibited from being used. Therefore, malfunction based on the non-reproducibility of the defect can be suppressed.

### 3. THIRD EMBODIMENT

Now, a semiconductor memory device and a memory system according to a third embodiment will be described. The third embodiment changes the defect detection condition in step S12 described in the first and second embodiments. Only differences from the first and second embodiment will be described below.

### 3.1 Test Method with Voltage Conditions Changed

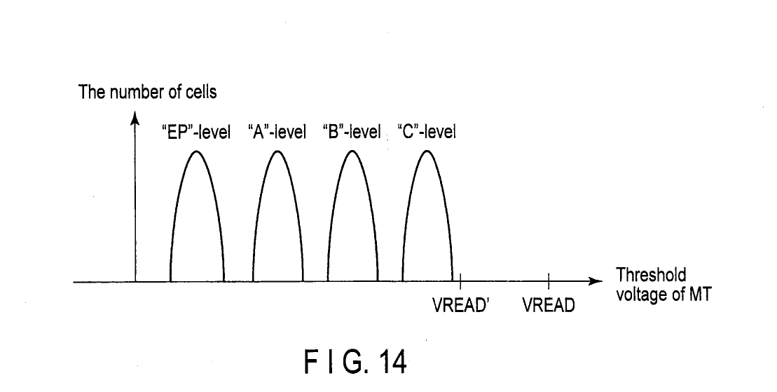

In the present example, a condition for voltages applied to a memory cell transistor MT is changed. A test method according to the present example will be described using FIG. 14. FIG. 14 is a diagram including threshold distributions for the memory cell transistor.

The third embodiment uses VREAD′ lower than VREAD as a voltage to be applied to a word line WL in step S12. In an example in FIG. 14, VREAD′ is set to a value higher than the “C” level and lower than VREAD.

The present method allows a defect difficult to detect to be discovered. As described above, the defects may include not only a complete defect that prevents the cell current from flowing through the memory cell transistor but also an incomplete defect. The incomplete defects include defects that allow a weak cell current to flow through the memory cell transistor. Such a defect allows the cell current to flow through the memory cell transistor to the degree that the memory cell transistor is determined to be an on cell. As a result, the memory cell may be determined to be non-defective.

In this regard, in the present example, the word line voltage used during defect detection is set lower than a voltage VREAD used for normal reading. In other words, during defect detection, the word line voltage is set to a value at which the memory cell is difficult to turn on. As a result, the incomplete defect causes the cell current to have more difficulty flowing, allowing such a memory cell to be restrained from being determined to be non-defective. In other words, the incomplete defect can be more efficiently detected.

### 3.2 Test Method with Timing Conditions Changed

In the present example, a defective NAND string is detected by changing a timing condition for defect detection. More specifically, a sense amplifier 13 makes a sense timing (strobe timing) earlier during defect detection than during normal reading.

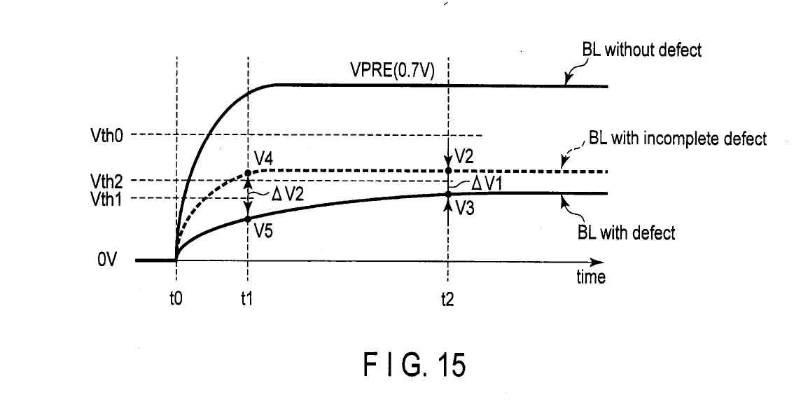

FIG. 15 is a timing chart illustrating changes in voltage during defect detection performed on bit lines BL, and corresponds to the variations in the voltages of the bit lines in FIG. 9 described in the first embodiment. FIG. 15 also shows a graph of a variation in the potential of a bit line BL which includes a defect but through which current flows relatively easily in addition to graphs of variations in the potentials of a bit line BL with defect and a bit line BL without defect.

As described in the first embodiment, whether or not a defect is present is determined by the sense amplifier 13 by comparing a predetermined threshold with the potential of the bit line BL resulting from reading of data from all the memory cell transistors.

As shown in FIG. 15, during defect detection and during reading, the potential of the bit line BL with a defect (complete defect) maintains a precharge level VPRE (for example, 0.7 V). In contrast, the potential of the bit line BL without a defect is lower than the precharge level VPRE. The bit line BL with an incomplete defect has a potential that is intermediate between the potential of the bit line BL with the complete defect and the potential of the bit line BL without the defect.

In the present example, during a normal reading operation, the sense amplifier 13 performs a sense operation (strobe operation) at time t2. The time t2 is when the potential of each of the bit lines BL reaches an approximately constant value after increasing from 0 V. In this case, the potential of the bit line BL with the incomplete defect is denoted by V2, and the potential of the bit line BL without the defect is denoted by V3 (<V2). Then, the sense amplifier 13 uses a potential Vth0 that is approximately intermediate between VPRE and V2 to perform determination on read data. That is, the sense amplifier 13 determines the read data to be “0” data when the potential of the bit line BL is higher than Vth0, and determines the read data to be “1” data when the potential of the bit line BL is lower than Vth0.

In contrast, during defect detection, the sense amplifier 13 performs a sense operation (strobe operation) using the time t1 that is earlier than the time t2. The time t1 is during a stage where the potential of each of the bit lines BL is increasing from 0 V. In this case, the potential of the bit line BL with the incomplete defect is denoted by V4, and the potential of the bit line BL without the defect is denoted by V5 (<V4). Then, the sense amplifier 13 uses a potential Vth1 that is approximately intermediate between V4 and V5 to perform determination on read data. That is, the sense amplifier 13 determines the read data to be “0” data (defective) when the potential of the bit line BL is higher than Vth1, and determines the read data to be “1” data (non-defective) when the potential of the bit line BL is lower than Vth1.

Also in the present example, the incomplete defect can be efficiently detected. That is, the cell current has more difficulty flowing through the bit line BL with incomplete defect than through the bit line BL without defect. Thus, immediately after the precharge potential VPRE is applied to the bit lines BL at time t0, the potential of the bit line BL with incomplete defect increases rapidly compared to the potential of the bit line BL without defect. However, the amount of cell current flowing through the bit line BL with incomplete defect is smaller than the amount of cell current flowing through the bit line BL without defect, the bit line BL with incomplete defect is saturated with a voltage V2 lower than the voltage VPRE. On the other hand, a weak leakage current also flows through the bit line BL without defect, and thus, the potential of the bit line BL without defect increases to V3 that is close to V2 by the time when approximately a given time elapses.

As a result, the difference in potential between the bit line BL with incomplete defect and the bit line BL without defect is ΔV1 (=V2-V3) at the time t2 and is ΔV2 (=V4-V5) at the time t1. Additionally, ΔV2>ΔV1. In the present example, with attention paid to this, a sense operation is performed at the point in time t1 when there is a significant difference in potential between the bit line BL with incomplete defect and the bit line BL without defect. A threshold used is Vth1, which is intermediate between V5 and V4.

In this regard, if sensing is performed at the time t2, Vth2, which is intermediate between V3 and V2, is used as a threshold. However, in this case, a reading margin is small because of the very small value of ΔV1. This may lead to erroneous reading.

In contrast, in the preset example, ΔV2 is larger than ΔV1, ensuring a sufficient reading margin. Thus, possible erroneous reading can be suppressed. In other words, the incomplete defect and the non-defective state can be accurately distinguished from each other.

### 3.3 Effect According to the Third Embodiment

As described above, various defects may occur in the NAND flash memory 100 and may be difficult to detect using the normal method. That is, such incompletely defective transistors are relatively easily turned on compared to completely defective memory cells. In other words, a relatively large amount of cell current flows through the incompletely defective transistors. Thus, the incompletely defective memory cells are difficult to determine to be defective.

Thus, the third embodiment uses a condition under which memory cells are unlikely to be turned on during defect detection. By way of example, such a word line voltage as described above may be set lower than during normal reading, or the sense timing is set earlier than during normal reading. As a result, defects that are difficult to detect can be detected, allowing the accuracy of defect detection. Of course, the condition is not limited to VREAD or the sense timing, and any condition may be used provided that memory cells are difficult to turn on under the condition.

### 4. FOURTH EMBODIMENT

Next, a semiconductor memory device and a memory system according to a fourth embodiment will be described. According to the fourth embodiment, in response to a test command from a controller 200 or a tester, the NAND flash memory 100 voluntarily sequentially issues string addresses to test a plurality of fingers. Only differences from the first to third embodiment will be described below.

### 4.1 Test Method

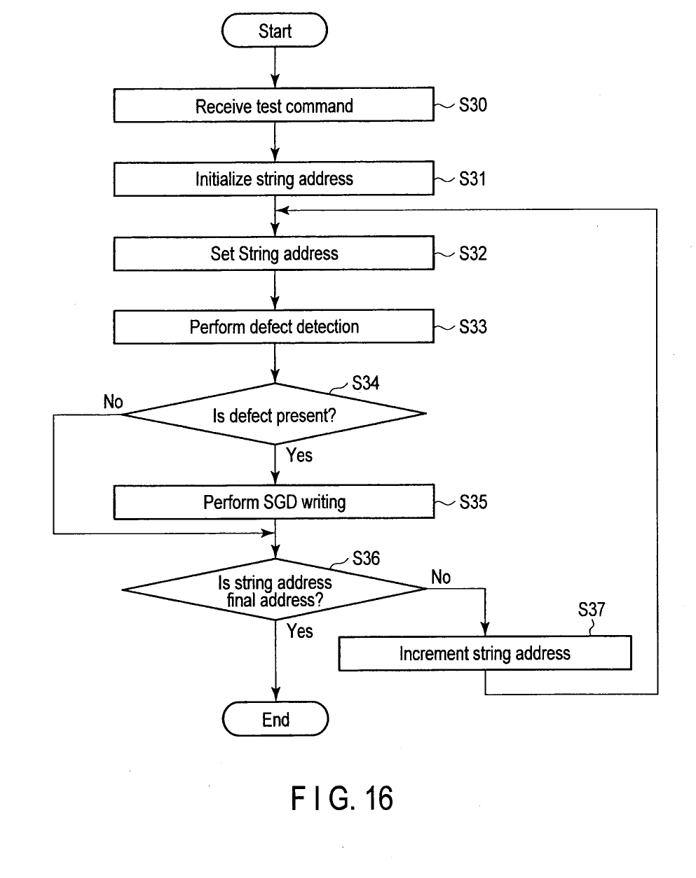

FIG. 16 is a flowchart of a test method according to the fourth embodiment.

As shown in FIG. 16, first, the controller 200 (or the tester) issues and transmits a test command to the NAND flash memory 100. Upon receiving the test command, the NAND flash memory 100 starts a test operation in response to the command (step S30). That is, the received test command is stored in a command register. In response to the test command, for example, the sequencer 16 initializes a string address (step S31) and sets an initial value for the string address (step S32). The sequencer 16 performs a defect detection operation using the method described in the first embodiment with reference to FIG. 8 and FIG. 9 (step S33). Step 33 is similar to step S12 described with reference to FIG. 6.

When step S12 results in the determination that a target NAND string 18 is defective (step S34, NO), the sequencer 16 performs SGD writing (step S35). Step S35 is similar to step S16 described with reference to FIG. 6. The fourth embodiment is different from the first embodiment in that the sequencer 16 voluntarily performs SGD writing without the need for a string address and a SGD write command from the controller 200.

Subsequently, the sequencer 16 determines whether or not the string address set in step S32 is the final address (step S36). The final address may be, for example, the final string address in any block BLK (in this case, each block is tested) or the final string address in a memory cell array 11 (in this case, all the blocks in the memory cell array 11 are tested).

When the tested address is not the final address (step S36, NO), the sequencer 16 increments the string address (step S37) and returns to step S32. The sequencer 16 then performs a test operation on the next finger FNG.

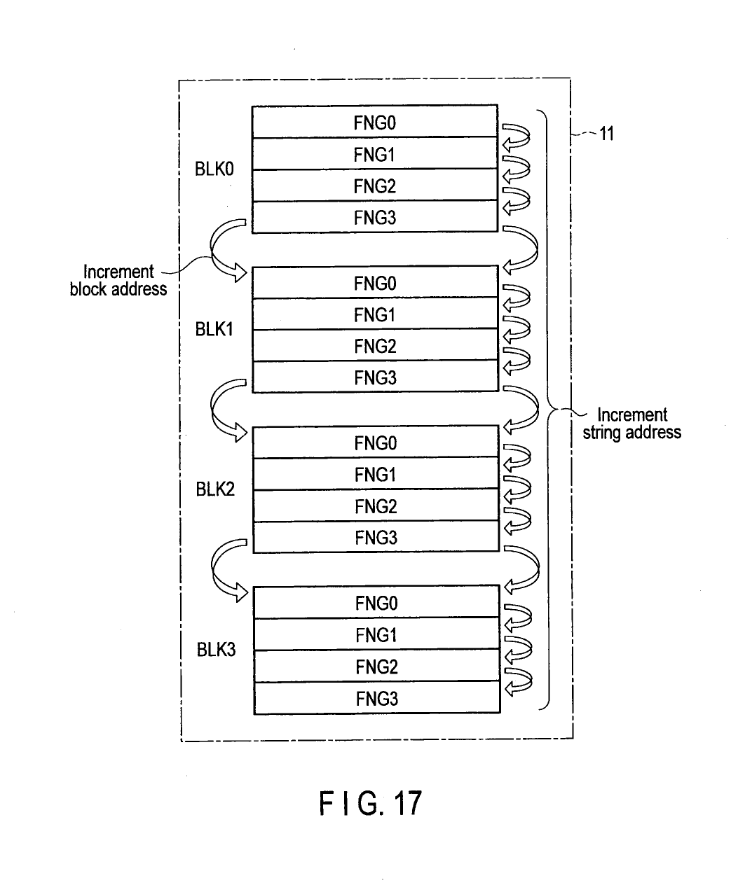

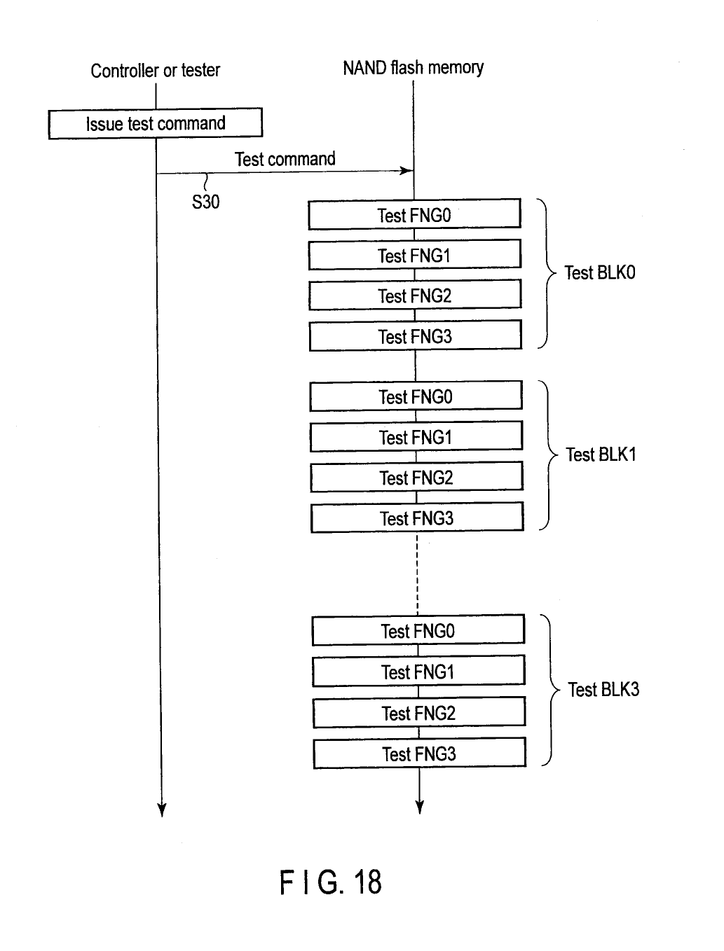

FIG. 17 and FIG. 18 show a specific example of the fourth embodiment. FIG. 17 is a block diagram of the memory cell array 11 showing a case where, by way of example, the memory cell array 11 includes four blocks BLK0 to BLK3 and each block BLK includes four fingers FNG0 to FNG3.

As shown in FIG. 18, the controller 200 (or the tester) issues a test command. Then, in response to the test command, the sequencer 16 issues a string address corresponding to the finger FNG0 in BLK0. The sequencer 16 then performs tests (defect detection and SGD writing) on the finger FNG0 in BLK0. The sequencer 16 subsequently increments the string address to sequentially test the fingers FNG1 to FNG3 in BLK0.

Then, the sequencer 16 increments the string address (more specifically, increments a block address) to test the finger FNG0 in the block BLK1. The sequencer 16 subsequently tests the fingers FNG1 to FNG3 in the block BLK1.

Subsequently, the sequencer similarly tests the blocks BLK2 and BLK3. When the test on the finger FNG3 in the block BLK3 completes, the sequencer 16 ends the processing.

### 4.2 Effect According to the Fourth Embodiment

The fourth embodiment reduces loads on the controller 200 and the tester.

According to the fourth embodiment, upon receiving the test command, the NAND flash memory 100 voluntarily issues a string address to test a plurality of fingers FNG. Thus, the controller 200 and the tester need not issue a command or an address each time the finger FNG to be tested is switched. This enables a reduction in loads on the controller 200 and the tester and allows the test operation to be performed faster.

Moreover, the fourth embodiment may also be executed after shipping of a memory system 1. Thus, even defects occurring during the use of the memory system 1 after shipment can be dealt with. That is, if any of the NAND strings 18 goes defective during use, the NAND flash memory 100 can inhibit this NAND string 18 from being used by writing defect information to a selection transistor ST1 or ST2 during a free time.

### 5. FIFTH EMBODIMENT

Now, a semiconductor memory device and a memory system according to a fifth embodiment will be described. The fifth embodiment relates to a write operation and a data read operation performed, after shipment, in the memory system 1 described in the first to fourth embodiments. Only differences from the first to fourth embodiment will be described below.

### 5.1 Write Operation

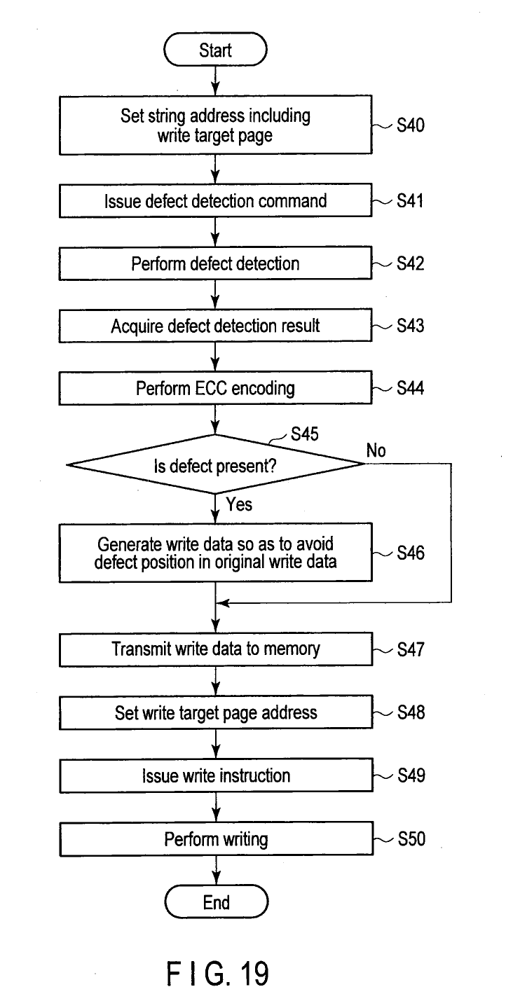

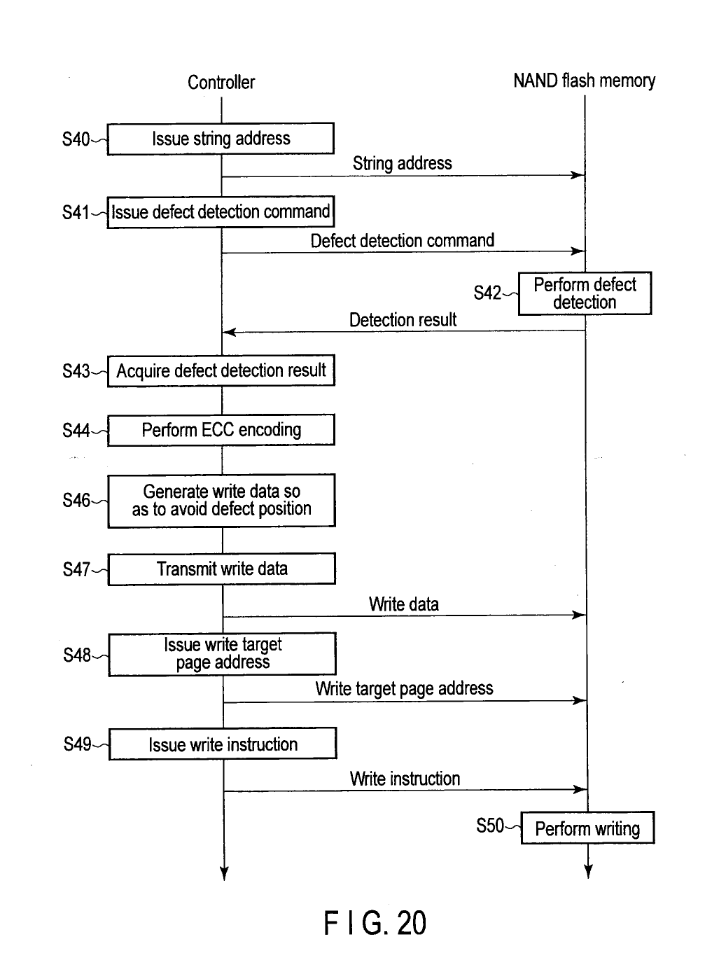

First, a write operation performed by the present memory system will be described using FIG. 19 and FIG. 20. FIG. 19 and FIG. 20 are flowcharts of data writing.

First, a processor 230 of a controller 200 issues and transmits a string address including a write target page to a NAND flash memory 100 (step S40). Subsequently, the processor 230 of the controller 200 issues and transmits a defect detection command to the NAND flash memory 100 (step S41). A sequencer 16 in the NAND flash memory 100 performs a defect detection operation on the string address specified in step S40 (step S42). The above-described processing is similar to steps S10 to S12 according to the first embodiment.

After executing step S42, the sequencer 16 in the NAND flash memory 100 transmits a defect detection result to the controller 200. As is the case with the first embodiment, the defect detection result may be transmitted from the NAND flash memory 100 to the controller 200 in the form of, for example, a defect detection signal. Alternatively, the defect detection result may be stored in any of the registers in the register 17 so that the controller 200 can read the information in the register 17. The defect detection result is stored in, for example, an embedded 220. Based on the defect detection result, the processor 230 of the controller 200 determines whether or not a finger including a write target page includes a defect (step S43).

Subsequently, an ECC circuit 260 of the controller 260 encodes write data. That is, the processor 230 transfers original data received in a buffer memory 240 from host device, to the ECC circuit 260. Then, the ECC circuit 260 generates parities based on the received original data and adds the generated parities to the original data to generate write data (step S44).

Moreover, if the finger including the write target page includes a defect (step S45, YES), the processor 230 or ECC circuit 260 of the controller 200 reconstructs the write data so as to avoid using the defective bit (step S46). More specifically, the bit is skipped to shift the bit string toward lower bits. A redundant bit is used as an extra bit needed as a result of skipping of the defective bit. If the finger does not include defective bit (step S45, NO), the write data is not reconstructed.

Subsequently, the processor 230 or ECC circuit 260 of the controller 200 transmits the write data to the NAND flash memory 100 (step S47). Then, the processor 230 of the controller 200 issues and sequentially transmits a write target address and a write command to the NAND flash memory 100 (steps S48 and S49).

Then, in response to the received write command, the sequencer 16 of the NAND flash memory 100 writes the data received in step S47 to a page corresponding to the address received in step S48 (step S50). During data writing, a row decoder 12 applies a voltage VSG to a selection gate line SGD, applies a voltage VPASS to unselected word lines WL, and applies a voltage VPGM to a selected word line WL. Moreover, a sense amplifier 13 applies 0 V to a write target bit line BL (write data is “0”) and applies V1 to non-write-target bit lines BL (write data is “1”). As a result, in the NAND string 18 connected to the write target bit line BL, the selection transistor ST1 is turned on to set the potential of a channel in the NAND string 18 to 0 V. Consequently, charge is injected into a memory cell transistor MT connected to the selected word line WL. On the other hand, in the NAND strings 18 connected to the non-write-target bit lines BL, the selection transistor ST1 is cut off. As a result, the channel in each of the NAND strings 18 electrically floats and is coupled with the word lines WL and a dummy word line DWL to increase the potential of the channel. This prevents data from being written to the memory cell transistors MT in the NAND string 18.

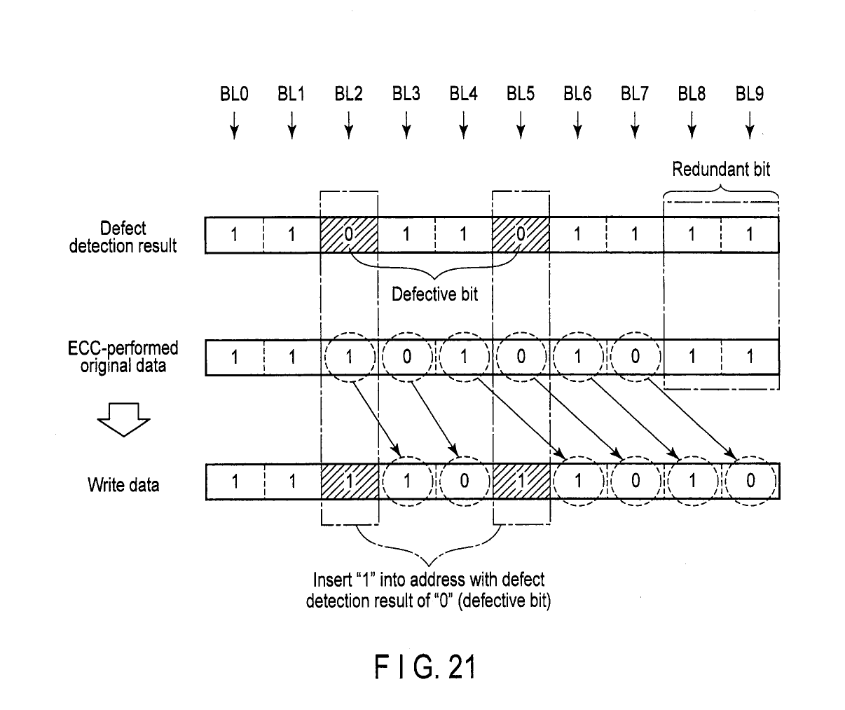

Step S46 will be described below in detail with reference to a specific example. FIG. 21 is a schematic diagram of the defect detection result (page data) obtained in step S42, the encoded original data obtained in step S44, and the write data reconstructed in step S46. In FIG. 21, defective bits are shaded. For simplification, by way of example, a case will be described where one page is 10 bit data including an 8 bit normal data area and a 2 bit redundant data area.

As shown in FIG. 21, the page data resulting from step S41 is assumed to be “1101101111”. That is, bits corresponding to bit lines BL2 and BL5 have been determined to be defective.

Furthermore, the write data obtained in step S44 is assumed to be “1110101011”. The net data is the first 8 bits, and the last 2 bits are redundant data.

Then, the processor 230 or the ECC circuit 260 reconstructs the write data based on the defect detection result. That is, the NAND string 18 corresponding to the third from the highest bit is defective, and thus, the processor 230 or the ECC circuit 260 skips a bit line BL3 corresponding to the third bit. In other words, the third and subsequent bits of the write data are shifted backward (toward lower bits). Then, the 5th bit of the write data is shifted to the 6th data, but the bit line BL5 is also defective. Thus, the 5th and subsequent bits of the write data are further shifted backward (toward lower bits) by 1 bit. Moreover, the processor 230 or the ECC circuit 260 inserts “1” data into the 3rd and 6th bits which correspond to defects. The “1” data writing is writing intended to inhibit data from being programmed in the corresponding memory cell transistor and to suppress a variation in the threshold for the memory cell transistor MT (in other words, non-write data).

As a result, the encoded original data “1110101011” is reconstructed into “1111011010”. As described above, the “1” data in the 3rd and 6th bits indicates that the bits are defective and are not net data. The reconstructed data thus generated is transferred from the controller 200 to the sense amplifier 13 in the NAND flash memory 100.

### 5.2 Read Operation

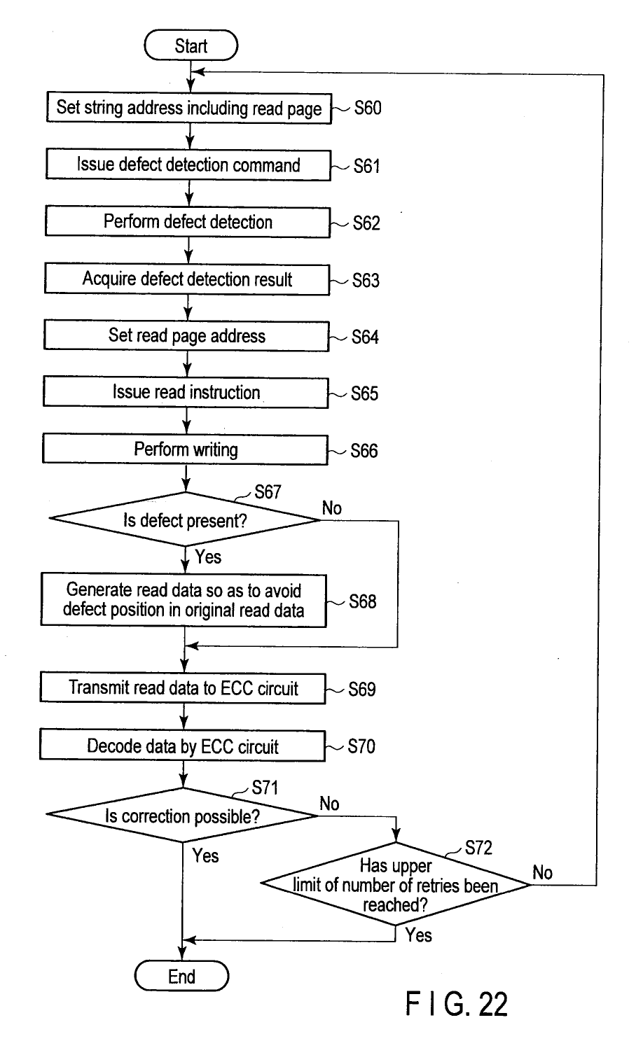

Now, a read operation performed by the present memory system will be described using FIG. 22. FIG. 22 is a flowchart of data reading.

First, the processor 230 of the controller 200 issues and transmits a string address to the NAND flash memory 100 (step S60). The processor 230 of the controller 200 subsequently issues and transmits a defect detection command to the NAND flash memory 100 (step S61). The sequencer 16 of the NAND flash memory 100 performs a defect detection operation on a string address specified in step S60 (step S62). The above-described processing is similar to steps S10 to S12 described in the first embodiment.

After executing step S62, the sequencer 16 of the NAND flash memory 100 transmits a defect detection result to the controller 200 same as in data writing. Based on the defect detection result, the processor 230 of the controller 200 can determine whether or not a finger including a write target page includes a defect (step S63). This processing is similar to step S43 during data writing.

The processor 230 of the controller 200 subsequently issues and transmits a read page address and a read instruction to the NAND flash memory 100 (steps S64 and S65).

Then, in response to the received read command, the sequencer 16 of the NAND flash memory 100 reads data from a page corresponding to the address received in step S64 (step S66). During data reading, a row decoder 12 applies a voltage VREAD to the unselected word lines WL and applies a voltage appropriate to a read level to the selected word line WL. The sequencer 16 transmits the read data to the controller 200. The read data is temporarily stored, for example, in a buffer memory 240.

If the finger including the read target page includes a defect (step S67, YES), the controller 200 discards data corresponding to this defect and reconstructs the read data (step S68). If the finger includes no defect (step S67, NO), the read data is not reconstructed.

Subsequently, the controller 200 transfers the read data from the buffer memory 240 to the ECC circuit (step S69). The ECC circuit decodes the transferred read data (step S70).

In step S70, if the decoding succeeds (step S71, YES), that is, if the read data is decodable data, the controller 200 transmits the result of the decoding to host device, completing the processing. On the other hand, if the decoding fails (step S71, NO), that is, if the read data is non-decodable data, the controller 200 repeats steps S60 to S71 until the number of retries reaches a preset upper limit value.

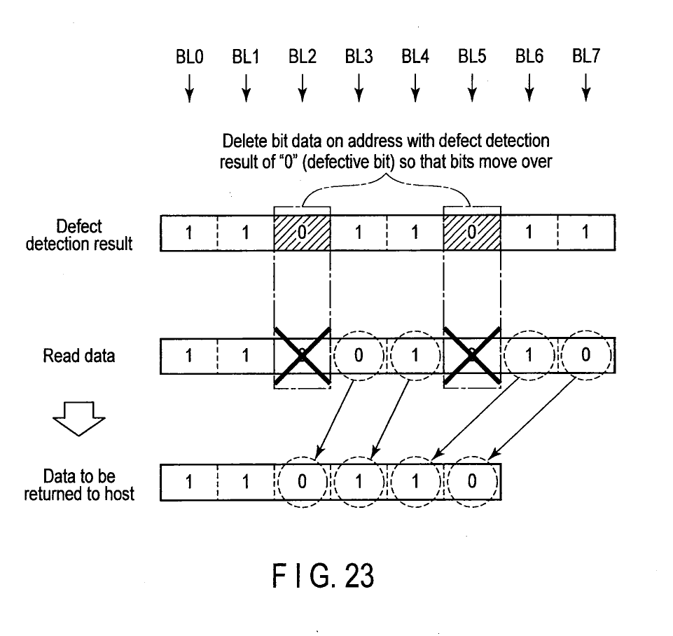

Step S68 will be described below in detail with reference to a specific example. FIG. 23 is a schematic diagram of the defect detection result (page data) obtained in step S62, the read data obtained in step S66, and the read data reconstructed in step S68. In FIG. 23, defective bits are shaded. For simplification, by way of example, a case where one page is 8 bit data will be described below.

As shown in FIG. 23, the page data resulting from step S62 is assumed to be “11011011”. That is, bits corresponding to the bit lines BL2 and BL5 have been determined to be defective.

Furthermore, the write data obtained in step S66 is assumed to be “11001010”.

Then, the processor 230 or the ECC circuit 260 reconstructs the read data based on the defect detection result. That is, the NAND string 18 corresponding to the third from the highest bit is defective, and thus, the processor 230 or the ECC circuit 260 discards the third bit of the read data. Then, the processor 230 or the ECC circuit 260 shifts the 4th and subsequent bits forward (toward higher bits). Furthermore, the 6th bit of the read data corresponds to a defect, the 6th bit is discarded, and the 7th and subsequent bits are further shifted forward (toward higher bits) by 1 bit.

As a result, the read data “11001010” transmitted by the NAND flash memory 100 is reconstructed into “110110”. This 6 bit data is transmitted to the host device.

### 5.3 Effect According to the Fifth Embodiment

When the defect information is managed as described in the first to fourth embodiments, such a method as provided by the fifth embodiment is applicable to data reading and writing.

According to the fifth embodiment, before writing and reading, the defect information written to the selection transistor ST1 and/or ST2 is read. Thus, the controller 200 can obtain information indicating whether or not the access target finger includes a defect and which of the bits is defective. Thus, writing accuracy and reading accuracy can be improved.

That is, net data can be prevented from being written to a defective bit during writing. More specifically, in the original data received from the host device, the bit corresponding to the defective bit is shifted toward lower bits (the bit may be shifted toward higher bits depending on the position of a redundant area). Then, meaningless data is written to the defective bit. In the present example, the “1” data is written. Writing of the “1” data causes the selection transistor ST1 to be cut off. Thus, the channel in the NAND string electrically floats and is coupled with the word line WL to increase the potential of the channel. Therefore, undesirable stress can be restrained from being applied to the memory cell transistors MT included in the NAND string 18.

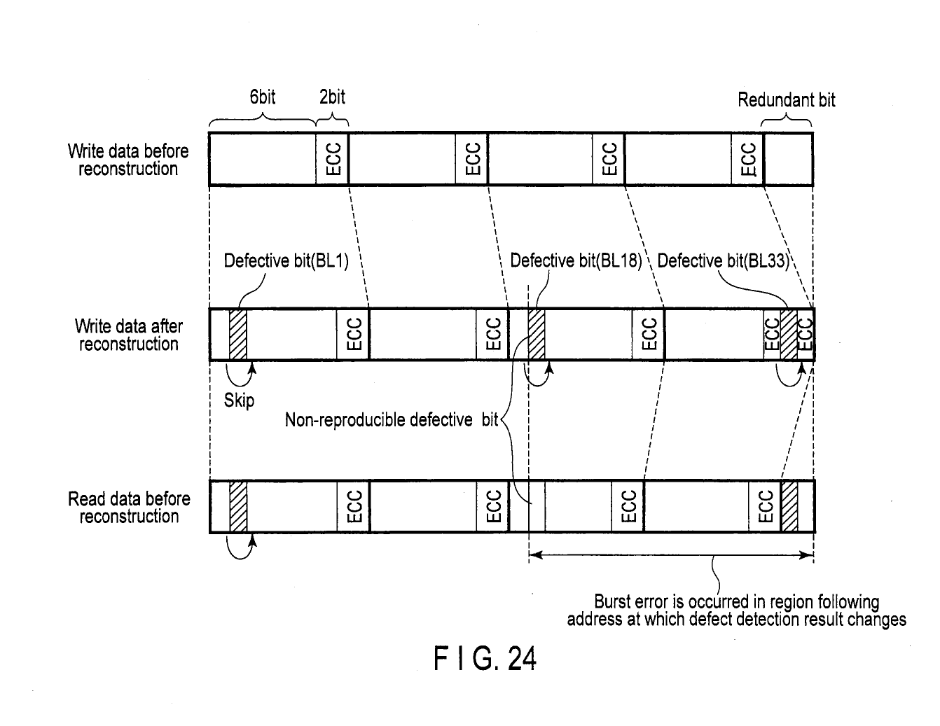

On the other hand, in data reading, the meaningless data inserted during, writing is discarded, allowing the correct data to be obtained. Moreover, if error correction fails to be achieved during reading (step S71 in FIG. 22), a defect detection operation and a reading operation are repeated again. This allows erroneous reading to be suppressed which is based on the mismatch between the defect detection result during writing and the defect detection result during reading. This will be described using FIG. 24. FIG. 24 is a schematic diagram of write page data encoded by the controller 200 but not reconstructed yet, write page data reconstructed during writing, and read page data not reconstructed yet. By way of example, FIG. 24 shows a case where a 2 bit parity is added to 6 bit original data, and four sets each of the 2 bit party and the 6 bit original data and additional redundant bits form one page.

As described in the second embodiment, the defects include defects constantly showing defective behavior and defects showing different behavior depending on the situation. The latter defects are sometimes determined to be defective but sometimes determined to be non-defective. FIG. 24 shows that such a defect is included in the access target page.

As shown in FIG. 24, it is assumed that, in a defect detection operation during writing (step S42), bit lines BL1, BL18, and BL33 are detected to be defective. Thus, as described with reference to FIG. 21, “1” is inserted into bits corresponding to the bit lines BL1, BL18, and BL33 to reconstruct the write data. In other words, the meaningless data is stored in the 2nd bit, the 19th bit, and the 34th bit of the write data. Thus, these data need to be discarded during reading.

However, as shown in FIG. 24, it is assumed that, in a defect detection operation during reading (step S62), only the bit lines BL1 and BL33 have been detected to be defective, whereas the bit line BL18 has been determined to be non-defective. This means that the bit line BL showed defective behavior during writing but showed non-defective behavior during reading.

In this case, when the read data reconstructed based on the defect detection result in step S62 is decoded, the ECC circuit 260 determines the 19th and subsequent bits to be all erroneous, and correcting the error is impossible (burst error). This is because the ECC circuit 260 determines the 19th bit with the meaningless data stored therein to be valid, so that all of the 19th and subsequent bits are shifted by 1 bit between the write data and the read data.

Thus, according to the fifth embodiment, if the ECC circuit 260 fails in error correction, defect detection and data reading are repeated until the error correction succeeds or until the number of retries reaches the upper limit value. In other words, defect detection and reading are repeated until the defect detection result during reading matches the defect detection result during writing. Moreover, In other words, when the read target page contains a non-reproducible bit, defect detection and reading are repeated until all of the defects during writing are reproduced.

Thus, even if any non-reproducible defect is present, data can be correctly read.

### 6. SIXTH EMBODIMENT

Now, a semiconductor memory device and a memory system according to a sixth embodiment will be described. The sixth embodiment corresponds to the first to fifth embodiments in which a dummy word line is provided adjacent to each of selection gate lines SGD and SGS and in which defect information is written to a dummy cell transistor connected to the dummy word line. Only differences from the first to fifth embodiment will be described below.

### 6.1 Configuration of the Memory Cell Array

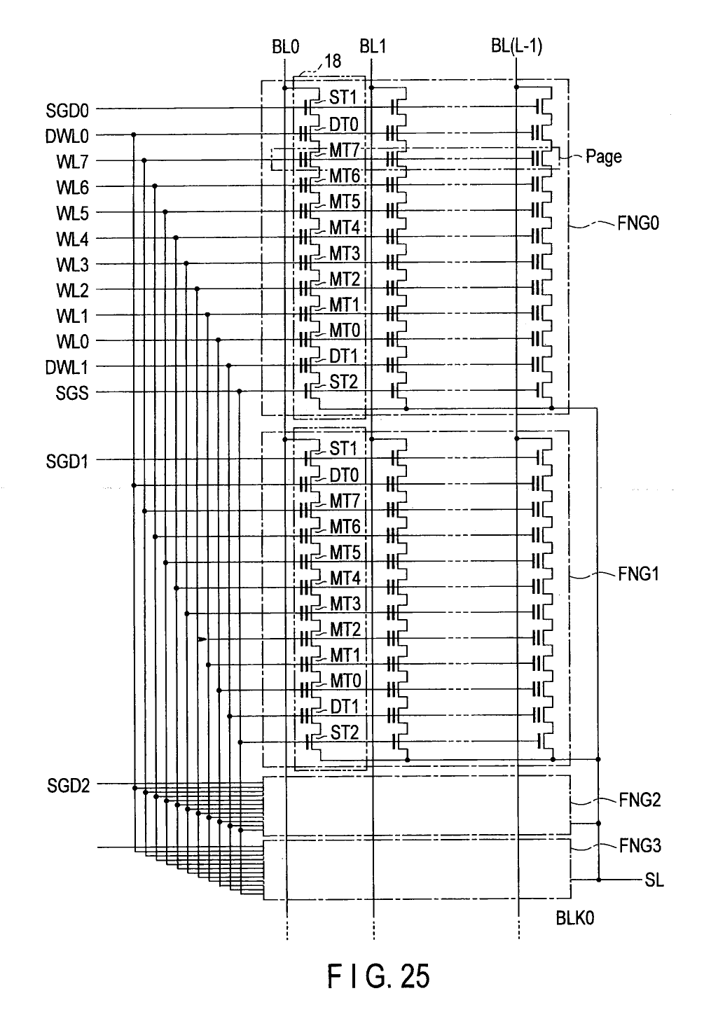

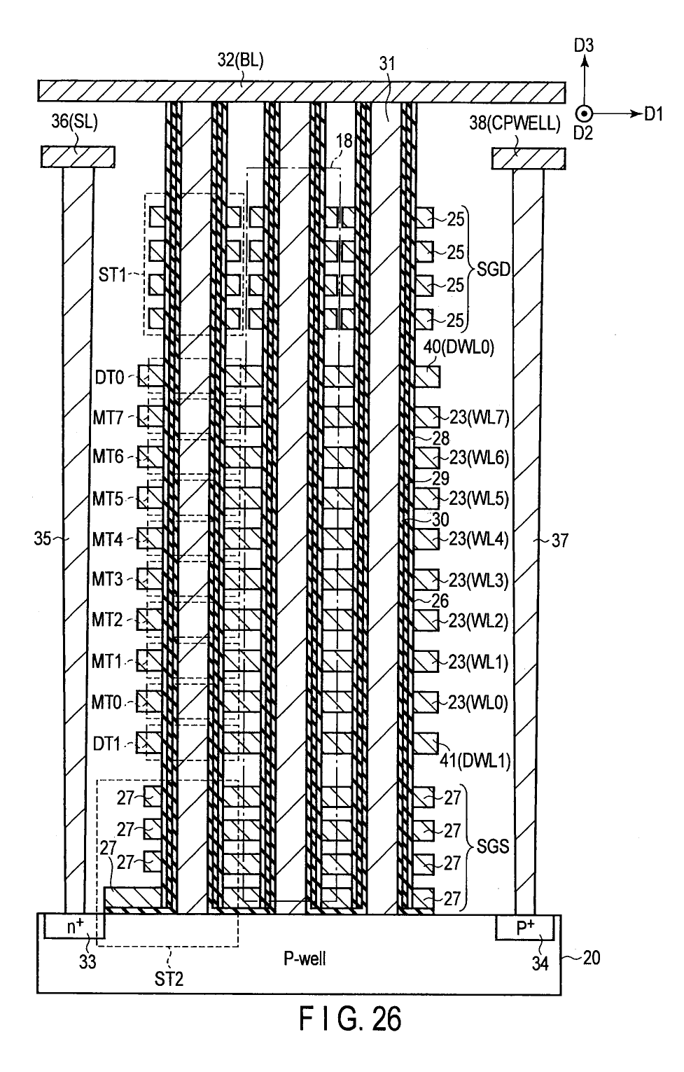

First, a configuration of a memory cell array 11 according to the sixth embodiment will be described. FIG. 25 and FIG. 26 are a circuit diagram and a cross-sectional view of the memory cell array 11 according to the sixth embodiment.

As shown in FIG. 25 and FIG. 26, the memory cell array 11 according to the sixth embodiment corresponds to the configuration described in the first embodiment with reference to FIG. 3 and FIG. 4 in which dummy word lines DWL and dummy cell transistors DT (DT0 and DT1) are provided.

More specifically, each NAND string 18 further includes two dummy cell transistors DT (DT0 and DT1). The dummy cell transistor DT0 is provided between a selection transistor ST1 and a memory cell transistor MT7 so that a current path in the dummy cell transistor DT0 is connected in series with the selection transistor ST1 and the memory cell transistor MT7. The dummy cell transistor DT1 is provided between a selection transistor ST2 and a memory cell transistor MT0 so that a current path in the dummy cell transistor DT0 is connected in series with the selection transistor ST2 and the memory cell transistor MT0. The dummy cell transistors DT0 in fingers FNG0 to FNG3 in a block BLK are all connected to a dummy word line DWL0. The dummy cell transistors DT1 in the fingers FNG0 to FNG3 in the block BLK are all connected to a dummy word line DWL1.

The dummy word lines DWL0 and DWL1 are selected or unselected by a row decoder 12, and appropriate voltages are applied to the dummy word lines DWL0 and DWL1 by the row decoder 12.

The dummy cell transistor DT is configured similarly to a memory cell transistor MT. That is, a gate insulating film 30 is formed around a conductive film 31, and a charge accumulation layer 29 and a block insulating film 28 are further formed. Control gates 40 and 41 are formed which function as the dummy word lines DWL. However, the dummy cell transistor DT is not used to actually hold net data provided by a host. The dummy cell transistor DT is turned on when a NAND flash memory operates (during data reading and during data writing), to function as a simple current path.

In the sixth embodiment, defect information is written to the dummy cell transistor DT0 and/or the dummy cell transistor DT1.

A plurality of the dummy cell transistors DT may be provided, and the number of dummy word lines DWL increases consistently with the number of dummy cell transistors DT. A plurality of dummy word lines DWL may be provided on a drain side and on a source side.

### 6.2 Threshold Distribution for Dummy Cell Transistor DT

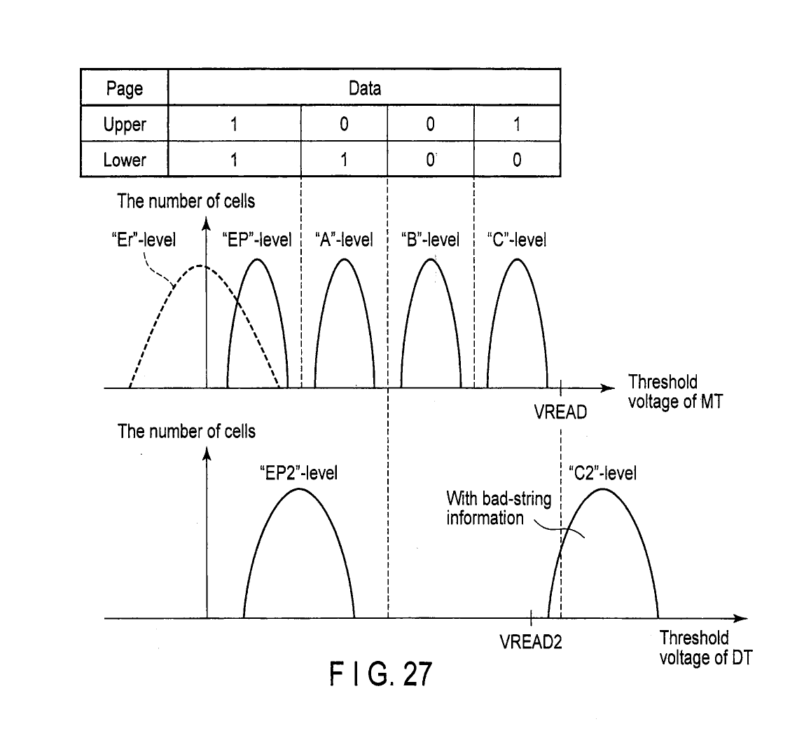

Now, a threshold distribution for the dummy cell transistor DT will be described. FIG. 27 is a graph showing threshold distributions for the memory cell transistor MT and the dummy cell transistor DT according to the sixth embodiment.

As shown in FIG. 27, during a normal read operation, VREAD2 is applied to the dummy word line DWL, and VREAD2 VREAD. When no defect information is written to the dummy cell transistor DT, a threshold for the dummy cell transistor is normally an “EP2” level. The “EP2” level is approximately an “EP” level to an “A” level and is a level at which the dummy cell transistor DT is turned on during normal reading (when VREAD2 is applied).

On the other hand, the threshold for the dummy cell transistor DT with the defect information written thereto is a “C2” level that is higher than VREAD2. The “C2” level is a level at which the dummy cell transistor DT is turned off during normal reading (when VREAD2 is applied). When VREAD2=VREAD, the threshold for the dummy cell transistor DT with the defect information written thereto is higher than the “C” level.

A threshold for selection transistors ST1 and SY2 is an “SG/EP” level.

### 6.3 Method for Detecting a Defect and Writing Defect Information

A method for testing the memory cell array 11 according to the sixth embodiment is substantially as described in the first to fourth embodiments. Only differences from the first to fourth embodiments will be described below.

### 6.3.1 Details of the Method for Detecting a Defect

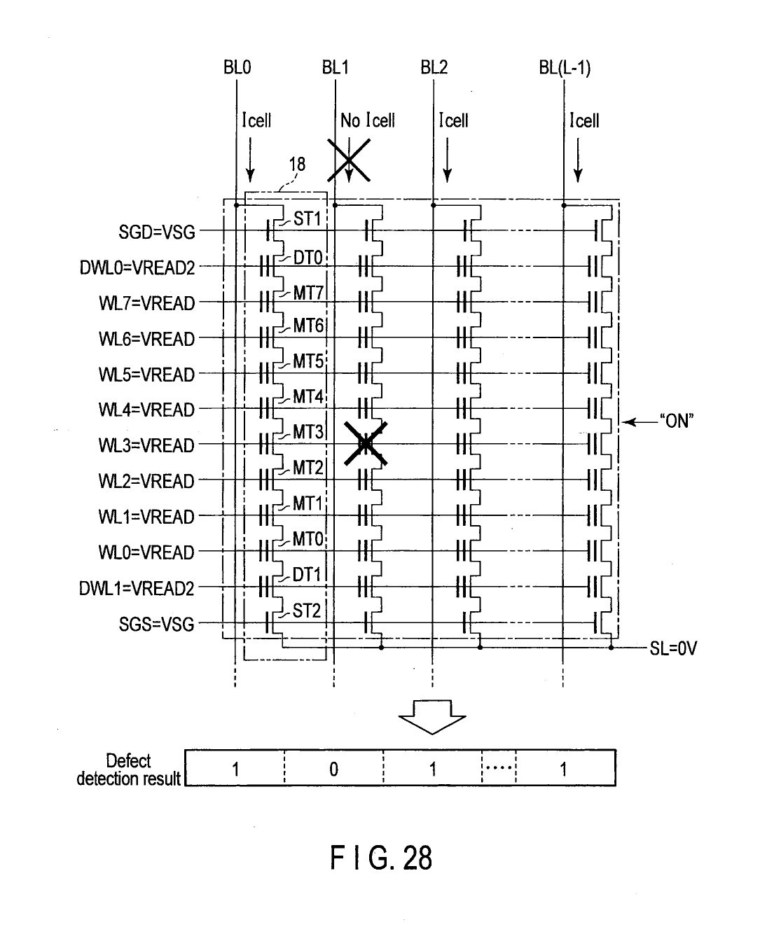

First, the details of a method for detecting a defect according to the sixth embodiment will be described. FIG. 28 is a circuit diagram of the memory cell array 11 according to the sixth embodiment, showing that a defect is detected.

As shown in FIG. 28, when a defect is detected, the row decoder 12 applies VREAD2 to the dummy word lines DWL0 and DWL1 and turns the non-defective dummy cell transistor DT on.

The remaining part of the method is as described in the first embodiment. That is, a sense amplifier 13 senses a current flowing through a bit line BL or the voltage of the bit line BL to determine whether the defect is present or not.

Of course, according to the sixth embodiment, the voltage applied to the dummy word line DWL during defect detection may be set lower than VREAD2 or the sense timing during defect detection may be set earlier than during normal reading, for example, as is the case with the second embodiment.

### 6.3.2 Details of the Method for Writing Defect Information

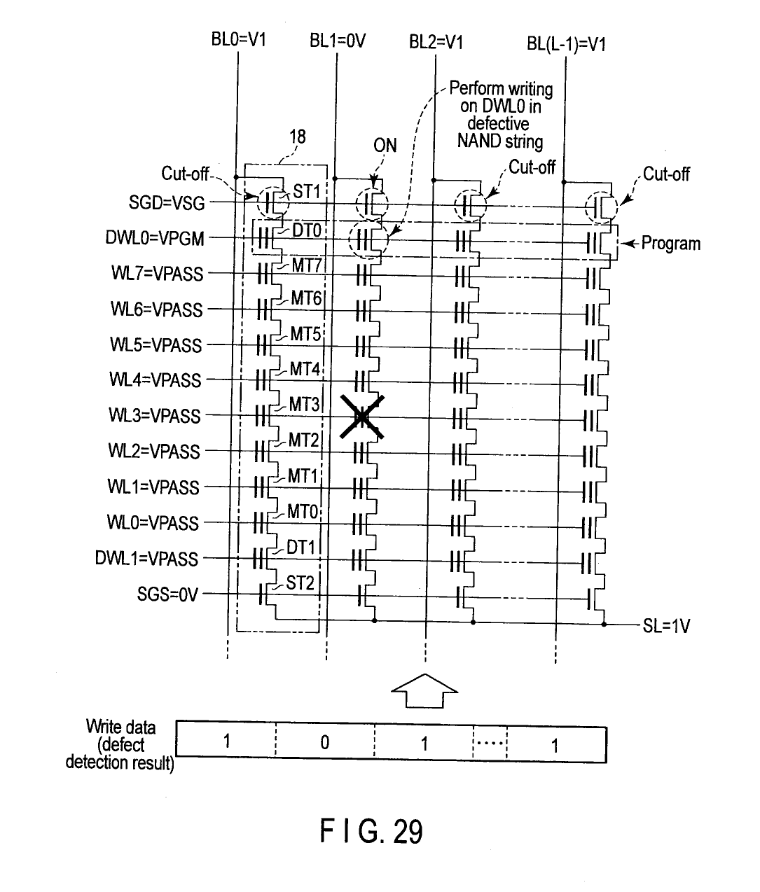

Now, the details of a method for writing defect information according to the sixth embodiment will be described. FIG. 29 is a circuit diagram of the memory cell array 11 according to the sixth embodiment, showing how defect information is written. By way of example, a case will be described below where the defect information is written to the dummy cell transistor DT0. The defect information may be written either to DT0 or to DT1.

As shown in FIG. 29, in writing the defect information, the row decoder 12 applies VSG to the selection gate line SGD, applies 0 V to the selection gate line SGS, and applies VPASS to the dummy word line DWL1 and all word lines WL0 to WL7. The row decoder 12 further applies a program voltage VPGM to the dummy word line DWL0.

As a result, in the NAND string 18 to which the defect information is to be written, the selection transistor ST1 is turned on. Thus, 0 V is transferred through a bit line BL1 to the channel formed in the NAND string 18. Therefore, the defect information is programmed in the dummy cell transistor DT0. At this time, the write verify voltage is equal to or higher than the voltage VREAD2. As a result, the threshold of the dummy cell transistor DT0 increases from the “EP2” level to the “C2 level”.

On the other hand, in the NAND string 18 to which the defect information is not to be written, the selection transistor ST1 is cut off. Thus, the channel formed in the NAND string 18 electrically floats. The channel is then coupled with the word line WL and the dummy word line DWL to increase the potential of the channel, with no data written to the dummy cell transistor DT0. That is, the threshold for the dummy cell transistor DT0 maintains the “EP2 level”.

### 6.4 Method for Normal Writing and Reading

The method for normal writing and reading in the semiconductor memory device and the memory system according to the sixth embodiment is as described in the fifth embodiment.

That is, the normal writing operation is as described with reference to FIG. 19. However, the defect detection operation in step S42 is performed as described with reference to FIG. 28. Furthermore, the normal reading operation is as described with reference to FIG. 22. However, the defect detection operation in step S62 is performed as described with reference to FIG. 28.

### 6.5 Effect According to the Sixth Embodiment

As described in the sixth embodiment, the defect information may be written to the dummy cell transistor DT instead of the selection transistors ST1 and ST2.

Even in this case, the dummy cell transistor DT is constantly off during normal reading, allowing effects similar to the effects of the above-described embodiments to be produced.

### 7. MODIFICATIONS AND THE LIKE

As described above, a semiconductor memory device 100 according to the embodiments includes: a plurality of transistors MT, DT, ST; a plurality of NAND strings 18; a bit line BL; a source line SL; and a plurality of string sets FNG. Each of the transistors MT includes a charge accumulation layer and a control gate and is stacked above a semiconductor substrate. Each of the NAND strings 18 includes a plurality of the transistors MT connected in series. Each of the string sets FNG includes a plurality of the NAND strings 18. The bit line BL is electrically connected to a one end of a first transistor ST1, DT0 positioned on a one end side of the series connection. The source line SL is electrically connected to a one end of a second transistor ST2, DT1 positioned on another end side of the series connection. In one of the string sets FNG, the first transistor ST1, DT0 in a first NAND string has a first threshold (“SG/AC” or “C2”), and the first transistor ST1, DT0 in a second NAND string has a second threshold (“SG/EP” or “EP2”) lower than the first threshold (FIG. 5, FIG. 10, and FIG. 27).

This configuration allows defects to be managed for each of the NAND strings 18. In other words, if one defective cell is present in any of the fingers FNG, only the NAND string including the defective cell may be exclusively handled as a defect (inhibited from being used). Thus, neither the whole finger nor the whole block needs to be handled as a defect, and memory areas can be more efficiently used.

The embodiments are not limited to the above-described embodiments, and various modifications may be made to the embodiments.

For example, the defect information may be written to the source side transistor ST2 instead of the drain side selection transistor ST1 or to both the selection transistors ST1 and ST2.

Furthermore, even if each of the NAND strings 18 can be remedy, the whole finger may be handled as a defect if one finger contains a large number of defective NAND strings. For example, the tester pre-holds a reference value for the number of defective NAND strings (for example, half the number of NAND strings 18 in one finger FNG) so that, when the number of defective NAND strings is larger than the reference value, the corresponding finger may be registered as a defective finger. This also applies to the controller 200. If, after a memory system 1 is shipped, the number of defective NAND strings increases and exceeds a certain reference value, the corresponding finger FNG may be registered as a defective finger FNG.

Additionally, the order of processes in the flowcharts described in the embodiments can be changed wherever possible and any of the processes may be omitted wherever possible. Moreover, the entity for executing each process may be changed between the NAND flash memory 100 and the controller 200. For example, step S14 in FIG. 6 and FIG. 12 may be omitted if the NAND flash memory 100 can continue to hold the address received in step S10 in any of the registers. In addition, the issuance of the SGD write command in FIG. 6 may follow step S11. Moreover, the merge process in step S21 described with reference to FIG. 12 may be executed by the controller 200. Then, the final merge result may be transmitted to the NAND flash memory 100 by the controller 200, for example, after step S20.

Moreover, the embodiments may be optionally combined together for implementation. For example, the second embodiment or the third embodiment may be combined with the sixth embodiment.

Moreover, the sixth embodiment has been described taking, as an example, the case where one dummy cell transistor DT is provided on the drain side and on the source side. However, two or more dummy cell transistors DT may be provided on the drain side and on the source side. In this case, the defect information may be written to any of the plurality of dummy cell transistors. That is, the defect information need not necessarily be written to the dummy cell transistor DT0 adjacent to the selection transistor ST1. Similar effects are exerted regardless of which of the dummy cell transistors the defect information is written to. Alternatively, the defect information may be written to a plurality of dummy cell transistors DT or to both the dummy cell transistor DT and the selection transistor ST.

Moreover, regardless of whether or not the dummy cell transistor DT is provided, the defect information may be written to one of the memory cell transistors MT. In this case, the threshold of the memory cell transistor MT is set to a level higher than the “C” level. Even in this case, similar effects are exerted because the memory cell transistor MT to which the defect information is written is constantly off during normal reading.

Furthermore, in the embodiments, each memory cell transistor MT holds 2 bit data by way of example. However, 1 bit data or 3 or more bit data may be held.

Moreover, in the embodiments, the semiconductor memory device is described taking the three-dimensional stacked NAND flash memory as an example. The three-dimensional stacked NAND flash memory 100 is not limited to the configuration in FIG. 3 and FIG. 4. For example, the semiconductor layer 26 may be U-shaped instead of being shaped like a pillar. Furthermore, the embodiments are not limited to the NAND flash memory but may be applied to configurations in general in which memory cells are three-dimensionally stacked and each have a selection gate.

Moreover, the embodiments are not limited to the configuration in which memory cells are three-dimensionally stacked. For example, the embodiments are applicable to a normal planar NAND flash memory 100 in which memory cell transistors MT and selection transistors ST are two-dimensionally arranged on a semiconductor substrate. Even in this case, the defect information can be written to the selection transistor ST by configuring the selection transistor ST similarly to the memory cell transistor MT.

While certain embodiments have been described, these embodiments have been presented by way of example only, and are not intended to limit the scope of the inventions. Indeed, the novel embodiments described herein may be embodied in a variety of other forms; furthermore various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. A semiconductor memory device comprising:
a plurality of transistors each including a charge accumulation layer and a control gate and stacked above a semiconductor substrate;
a plurality of NAND strings each including a plurality of the transistors connected in series,
a bit line electrically connected to a one end of a first transistor positioned on a one end side of the series connection;
a source line electrically connected to a one end of a second transistor positioned on another end side of the series connection; and
a plurality of string sets each including a plurality of the NAND strings,
wherein, in one of the string sets, the first transistor in a first NAND string has a first threshold, and the first transistor in a second NAND string has a second threshold lower than the first threshold.

2. The device according to claim 1, wherein the transistors connected in series include the first and second transistors and a plurality of memory cell transistors connected in series between the first transistor and the second transistor, and
the first and second transistors are selection transistors to select the memory cell transistors between the first transistor and the second transistor.

3. The device according to claim 1, wherein each of the NAND strings includes a first selection transistor connected between the bit line and the one end of the first transistor and a second selection transistor connected between the source line and the one end of the second transistor.

4. The device according to claim 1, further comprising:
a row decoder applying a first voltage to gates of the first and second transistors in data reading,
wherein, when the first voltage is applied to the gate, the first transistor with the first threshold is turned off, and the first transistor with the second threshold is turned on.

5. The device according to claim 4, further comprising:
a control circuit performing a test operation on each of the strings sets in response to an instruction received from outside; and
a sense amplifier sensing data read from the transistors,
wherein, in the test operation, the sense amplifier senses data read by the row decoder applying the first voltage to the gates of the first and second transistors, and applying a second voltage to gates of the transistors between the first transistor, the second voltage turning a non-defective transistor on regardless of held data.

6. The device according to claim 5, wherein, in the reading operation, the control circuit performs the test operation in response to the first instruction received from the outside and outputs a result of the test to the outside, and
the control circuit subsequently reads data from one of the string sets in units of page in response to a second instruction received from the outside.

7. The device according to claim 5, wherein, in the writing operation, the control circuit performs the test operation in response to the first instruction received from the outside and outputs a result of the test to the outside, and
the control circuit subsequently writes data to one of the string sets in units of page in response to a second instruction received from the outside.

8. The device according to claim 5, wherein the control circuit performs a program operation on the first transistor in accordance with a result of the test in the test operation to set the threshold to the first threshold from the second threshold.

9. The device according to claim 4, wherein, upon once receiving the instruction from the outside, the control circuit sequentially tests a plurality of the string sets by issuing an address designating a string set to be tested, without a need for the subsequent instruction from the outside.

10. The device according to claim 4, wherein, in the reading operation, the row decoder applies a third voltage to the transistors which are not selected between the first and second transistors, and
the second voltage is lower than the third voltage.

11. The device according to claim 4, wherein the sense amplifier senses data at first time in the reading operation and
senses data at second time before the first point in time during the test operation.

12. A memory system comprising:
a semiconductor memory device capable of holding data; and
a controller controlling the semiconductor memory device,
wherein the semiconductor memory device includes:
a plurality of transistors each including a charge accumulation layer and a control gate and stacked above a semiconductor substrate;
a plurality of NAND strings each including a plurality of the transistors connected in series,
a bit line electrically connected to a one end of a first transistor positioned on a one end side of the series connection;
a source line electrically connected to a one end of a second transistor positioned on another end side of the series connection; and
a plurality of string sets each including a plurality of the NAND strings,
wherein, in one of the string sets, the first transistor in a first NAND string has a first threshold, and the first transistor in a second NAND string has a second threshold lower than the first threshold.

13. The system according to claim 12, wherein the transistors connected in series include the first and second transistors and a plurality of memory cell transistors connected in series between the first transistor and the second transistor, and
the first and second transistors are selection transistors to select the memory cell transistors between the first transistor and the second transistor.

14. The system according to claim 12, wherein each of the NAND strings includes a first selection transistor connected between the bit line and the one end of the first transistor and a second selection transistor connected between the source line and the one end of the second transistor.

15. The system according to claim 12, wherein, in a data writing operation, the controller transmits a test command to the semiconductor memory device,
the semiconductor memory device performs a test operation on one of the string sets in response to the test command, and transmits a result of the test to the controller,
the controller updates write data in accordance with the result of the test and transmits the updated write data to the semiconductor memory device, and
the semiconductor memory device writes the updated write data to the transistor.

16. The system according to claim 15, wherein the controller updates the write data by inserting a first value into one of bits of the write data in accordance with the result of the test.

17. The system according to claim 16, wherein, in the test operation, a first voltage is applied to all word lines in the one of the string sets which is a write target, to read data from all transistors included in the write target string set,
a presence or an absence of a defect in a NAND string corresponding to any bit line is detected in accordance with a result of the reading, and
the controller sets the first value in a bit corresponding to a NAND string determined to be have a defect.

18. The system according to claim 15, wherein, in a data reading operation, the controller transmits a test command to the semiconductor memory device,
the semiconductor memory device performs a test operation on one of the string sets in response to the test command, and transmits a result of the test to the controller,
the controller transmits a read command to the semiconductor memory device,
the semiconductor memory device transmits the read data from the memory cell transistor to the controller in response to the read command, and
the controller reconstructs the read data in accordance with the result of the test.

19. The system according to claim 18, wherein in the test operation, a first voltage is applied to all word lines in the one of the string sets which is a read target, to read data from all transistors included in the read target string set,
a presence or an absence of a defect in a NAND string corresponding to any bit line is detected in accordance with a result of the reading, and
the controller deletes a bit corresponding to a NAND string determined to be have a defect.

20. The system according to claim 12, wherein the controller or a tester configured to test the semiconductor memory device
performs a plurality of tests operations on one of the strings sets in the semiconductor memory device, and
sets a threshold for any of the first transistors to the first threshold in accordance with results of the plurality of test operations.
